(19) United States
(12) Patent Application Publication
(10) Pub. No.: US 2016/0141111 A1
(43) Pub. Date: May 19, 2016

(54) PHOTOELECTRIC CONVERSION ELEMENT AND SOLAR CELL

(71) Applicant: FUJIFILM Corporation, Tokyo (JP)

(72) Inventors: Hirotaka SATO, Ashigarakami-gun (JP); Katsumi KOBAYASHI, Ashigarakami-gun (JP)

(73) Assignee: FUJIFILM Corporation, Tokyo (JP)

(21) Appl. No.: 15/001,984

(22) Filed: Jan. 20, 2016

Related U.S. Application Data
(63) Continuation of application No. PCT/JP2014/069464, filed on Jul. 23, 2014.

(30) Foreign Application Priority Data
Jul. 31, 2013 (JP) 2013-159473
Jul. 8, 2014 (JP) 2014-140941

(51) Int. Cl. H01G 9/20

(52) U.S. Cl. CPC H01G 9/2004

(57) ABSTRACT

A photoelectric conversion element includes a first electrode which has a photosensitive layer containing a light absorber on a conductive support, a second electrode which is opposed to the first electrode, and a hole transport layer which is provided between the first electrode and the second electrode, and the light absorber contains at least one of compound (P) having a perovskite crystal structure represented by the following Formula (I). A solar cell includes this photoelectric conversion element.

Aₐ(M^{A1}₍₁₋ₙ₎M^{A2}ₙ)_{mA}Xₓ Formula (I):

### CROSS-REFERENCE TO RELATED APPLICATIONS

This application is a Continuation of PCT International Application No. PCT/JP2014/069464 filed on Jul. 23, 2014, which claims priority under 35 U.S.C §119(a) to Japanese Patent Application No. 2013-159473 filed on Jul. 31, 2013 and Japanese Patent Application No. 2014-140941 filed on Jul. 8, 2014. Each of the above application(s) is hereby expressly incorporated by reference, in its entirety, into the present application.

### BACKGROUND OF THE INVENTION

1. Field of the Invention

The present invention relates to a photoelectric conversion element and a solar cell.

2. Description of the Related Art

Photoelectric conversion elements are used in various optical sensors, copiers, solar cells, and the like. Solar cells use inexhaustible solar energy and are expected to be put into real practical use. Among these, dye-sensitized solar cells using an organic dye, a Ru bipyridyl complex, or the like as a sensitizer are actively studied and developed, and the photoelectric conversion efficiency thereof reaches about 11%.

In recent years, a study result in which a solar cell using a metal halide as a compound having a perovskite crystal structure can achieve a relatively high photoelectric conversion efficiency has been reported and a patent application thereof has been filed, whereby this result has attracted attention.

For example, a solar cell having: a TiO₂ film adsorbing a compound having a perovskite crystal structure of CH₃NH₃PbX₃ (X represents a bromine atom or an iodine atom) as nano-sized fine particles; and an electrolyte solution is described in J. Am. Chem. Soc., 2009, 131 (17), 6050-6051.

In addition, a solar cell including: a light absorption layer including a semiconductor fine particle layer and a compound having a perovskite crystal structure represented by CH₃NH₃MX₃ (M represents Pb or Sn, and X represents a halogen atom); and an electrolyte layer formed of an electrolyte is described in KR10-1172374B.

A solar cell using: a compound having a perovskite crystal structure of CH₃NH₃PbI₂Cl; and a hole transport material has been studied and reported (Science, 338, 643 (2012)).

### SUMMARY OF THE INVENTION

As described above, a photoelectric conversion element and a solar cell using a compound having a perovskite crystal structure, that is, a metal halide, achieve a certain result in the improvement in the photoelectric conversion efficiency. However, the photoelectric conversion element and the solar cell have attracted attention in recent years, and cell performance other than the photoelectric conversion efficiency is little known.

In such a state, when repeatedly manufacturing the above-described solar cell through the same manufacturing method using a compound having a perovskite crystal structure, that is a metal halide, the variation in the photoelectric conversion efficiency between the obtained solar cells is great, and thus stability of the cell performance is found to be insufficient.

Accordingly, an object of the invention is to provide a photoelectric conversion element which exhibits stable cell performance with less fluctuation in the photoelectric conversion efficiency, and a solar cell including the photoelectric conversion element.

The inventors of the invention have performed various examinations on a solar cell (also referred to as perovskite-sensitized solar cell) using a compound having a perovskite crystal structure (also referred to as perovskite compound or perovskite light absorber) as a light absorber, and found that the type of the light absorber is important for stability of the photoelectric conversion efficiency. Furthermore, as a result of further detailed examination, they have found that in the photoelectric conversion element and the solar cell, the fluctuation in the photoelectric conversion efficiency can be reduced when substituting metal atoms constituting the perovskite compound with one of specific metal atoms or two of metal atoms mixed at a specific ratio and when using a specific cationic group as a cationic group. The invention has been completed based on this knowledge.

That is, the object is solved by the following means.

<1> A photoelectric conversion element including a first electrode which has a photosensitive layer containing a light absorber on a conductive support, a second electrode which is opposed to the first electrode, and a hole transport layer which is provided between the first electrode and the second electrode,

in which the light absorber contains at least one of compound (P) having a perovskite crystal structure represented by the following Formula (I).

Aₐ(M^{A1}₍₁₋ₙ₎M^{A2}ₙ)_{mA}Xₓ Formula (I):

In the formula, A represents a cationic group represented by the following Formula (A), M^{A1} and M^{A2} represent metal atoms different from each other, n represents a number satisfying 0≦n≦0.5, X represents an anionic atom, a represents 1 or 2, mA represents 1, and a, mA, and x satisfy a+2 mA=x.

R^{A}—NH₃ Formula (A):

In the formula, R^{A} represents an alkyl group, a cycloalkyl group, an alkenyl group, an alkynyl group, an aryl group, a heteroaryl group, or a group represented by the following Formula (1), which may have a substituent, and the alkyl group has a substituent when n represents a number satisfying 0≦n<0.01.

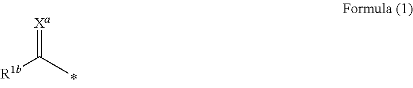

In Formula (1), X^{a} represents NR^{1c}, an oxygen atom, or a sulfur atom, each of R^{1b} and R^{1c} independently represents a hydrogen atom or a substituent, and * represents a bonding position with the N atom of Formula (A).

<2> The photoelectric conversion element according to <1>, in which the compound (P) having a perovskite crystal structure includes a compound (P^{A}) represented by the following Formula (IA).

A(M^{A1}₍₁₋ₙ₎M^{A2}ₙ)X₃ Formula (IA):

In the formula, A, M^{A1}, M^{A2}, n, and X are synonymous with A, M^{A1}, M^{A2}, n, and X of Formula (I).

<3> The photoelectric conversion element according to <1> or <2>, in which the compound (P) having a perovskite crystal structure includes a compound (P^{B}) represented by the following Formula (TB).

A₂(M^{A1}₍₁₋ₙ₎M^{A2}ₙ)X₄ Formula (IB):

In the formula, A, M^{A1}, M^{A2}, n, and X are synonymous with A, M^{A1}, M^{A2}, n, and X of Formula (I).

<4> The photoelectric conversion element according to any one of <1> to <3>, in which when n represents a number satisfying 0.01≦n≦0.5, A is a cationic group represented by the following Formula (A1).

R^{A1}—NH₃ Formula (A1):

In the formula, R^{A1} represents an unsubstituted alkyl group.

<5> The photoelectric conversion element according to any one of <1> to <3>, in which A is a cationic group represented by the following Formula (A2).

R^{A2}—NH₃ Formula (A2):

In the formula, R^{A2} represents an alkyl group having a substituent, or a cycloalkyl group, an alkenyl group, an alkynyl group, an aryl group, a heteroaryl group, or a group represented by Formula (1), which may have a substituent.

<6> The photoelectric conversion element according to any one of <1> to <5>, in which n represents a number satisfying 0.05≦n≦0.20.

<7> The photoelectric conversion element according to any one of <1> to <6>, in which one of M^{A1} and M^{A2} is a Pb atom and the other is a Sn atom.

<8> The photoelectric conversion element according to any one of <1> to <7>, in which M^{A1} is a Pb atom and M^{A2} is a Sn atom.

<9> The photoelectric conversion element according to any one of <1> to <8>, in which X is a halogen atom. <10> The photoelectric conversion element according to any one of <1>, <2>, and <4> to <9>, in which when a is 1, X is represented by the following Formula (X1).

X^{A1}₍₃₋ₘ₁₎X^{A2}ₘ₁ Formula (X1):

In the formula, X^{A1} and X^{A2} represent anionic atoms different from each other, and m1 represents a number of 0.01 to 2.99.

<11> The photoelectric conversion element according to any one of <1> and <3> to <9>, in which when a is 2, X is represented by the following Formula (X2).

X^{A1}₍₄₋ₘ₂₎X^{A2}ₘ₂ Formula (X2):

In the formula, X^{A1} and X^{A2} represent anionic atoms different from each other, and m2 represents a number of 0.01 to 3.99.

<12> The photoelectric conversion element according to <10> or <11>, in which X^{A1} and X^{A2} are halogen atoms different from each other.

<13> The photoelectric conversion element according to any one of <1> to <12>, in which the substituent has at least one selected from the group consisting of an alkyl group, a cycloalkyl group, an alkenyl group, an alkynyl group, an alkoxy group, an alkylthio group, a mercapto group, an aryloxy group, an amino group, a carboxy group, an acyl group, an alkoxycarbonyl group, an aryloxycarbonyl group, an alkyl carbonyloxy group, an aryl carbonyloxy group, a halogen atom, a cyano group, an aryl group, and a heteroaryl group.

<14> The photoelectric conversion element according to any one of <1> to <13>, in which the substituent is a halogen atom.

<15> The photoelectric conversion element according to any one of <1> to <13>, in which the substituent is an alkyl group substituted with a halogen atom.

<16> A solar cell including the photoelectric conversion element according to any one of <1> to <15>.

In this description, the respective formulae, particularly, Formulae (A), (A1), (A2), (1), and (A^{am}) may be partially expressed as rational formulae in order to understand the chemical structure of the compound having a perovskite crystal structure. With this, partial structures are called groups, substituents, atoms, or the like in the respective formulae, but in this description, these mean element groups or elements constituting the (substituent) groups represented by the above formulae.

In this description, regarding representation of compounds (including complex and dye), the compounds are used to mean not only the compounds themselves, but also salts and ions thereof. These also include compounds having a structure partially modified within the scope of causing target effects. Regarding compounds having no specification about substitution or unsubstitution, these mean compounds including compounds having an arbitrary substituent within the scope of causing desired effects. This is also applied to the cases of the substituent and the linking group (hereinafter, referred to as substituent and the like).

In this description, when there are more than one substituent and the like indicated by a specific reference, or when a plurality of substituents and the like are simultaneously specified, the respective substituents and the like may be the same as or different from each other unless otherwise mentioned. This is also applied to the case of the specification of the number of substituents and the like. In addition, when a plurality of substituents and the like are close to each other (particularly, adjacent to each other), these may be connected to each other and form a ring unless otherwise mentioned. In addition, rings such as an aliphatic ring, an aromatic ring, and a hetero ring may be condensed and form a condensed ring.

In this description, the numerical value range expressed using “to” means a range including the numerical values described before and after “to” as a lower limit value and an upper limit value.

According to the photoelectric conversion element and the solar cell of the invention, it is possible to suppress the fluctuation in the photoelectric conversion efficiency between solar cells even when repeatedly manufacturing the solar cells through the same manufacturing method. Accordingly, according to the invention, it is possible to provide a photoelectric conversion element which exhibits stable cell performance with less fluctuation in the photoelectric conversion efficiency, and a solar cell including the photoelectric conversion element.

### BRIEF DESCRIPTION OF THE DRAWINGS

FIG. 1 is a cross-sectional view schematically showing a preferred aspect of a photoelectric conversion element of the invention.

FIG. 2 is a cross-sectional view schematically showing a preferred aspect in which the photoelectric conversion element of the invention has a thick photosensitive layer.

FIG. 3 is a cross-sectional view schematically showing another preferred aspect of the photoelectric conversion element of the invention.

FIG. 4A, FIG. 4B, and FIG. 4C illustrate a crystal structure of a perovskite compound.

### DESCRIPTION OF THE PREFERRED EMBODIMENTS

<<Photoelectric Conversion Element>>

A photoelectric conversion element of the invention has a first electrode having a photosensitive layer containing a light absorber on a conductive support, a second electrode opposed to the first electrode, and a hole transport layer provided between the first electrode and the second electrode. The photosensitive layer, the hole transport layer, and the second electrode are preferably provided on the conductive support in this order.

The photosensitive layer is formed to contain a light absorber.

The light absorber includes at least one of perovskite compound (P) to be described later. The light absorber may include a light absorber other than the perovskite compound together with the perovskite compound (P). Examples of the light absorber other than the perovskite compound (P) include a metal halide, a metal complex dye, and an organic dye described in KR10-1172374B, J. Am. Chem. Soc., 2009, 131 (17), 6050-6051, and Science, 338, 643 (2012).

In the invention, the expression “having a photosensitive layer . . . on a conductive support” has a meaning including an aspect in which the photosensitive layer is provided in contact with a surface of the conductive support and an aspect in which the photosensitive layer is provided over the surface of the conductive support with other layers interposed therebetween.

In the aspect in which the photosensitive layer is provided over the surface of the conductive support with other layers interposed therebetween, other layers provided between the conductive support and the photosensitive layer are not particularly limited as long as these do not reduce cell performance of a solar cell. Examples thereof include a porous layer and a blocking layer.

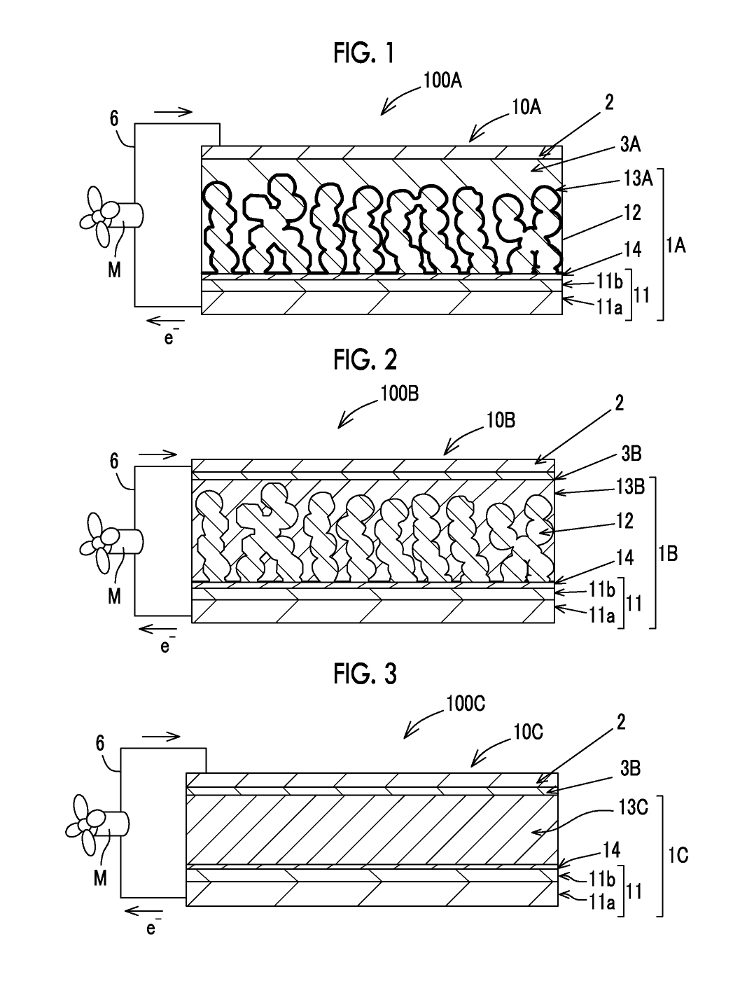

In the invention, examples of the aspect in which the photosensitive layer is provided over the surface of the conductive support with other layers interposed therebetween include an aspect in which the photosensitive layer is provided in a thin film shape or the like on a surface of a porous layer (see FIG. 1), an aspect in which the photosensitive layer is provided to have a large thickness on a surface of a porous layer (see FIG. 2), an aspect in which the photosensitive layer is provided to have a small thickness on a surface of a blocking layer, and an aspect in which the photosensitive layer is provided to have a large thickness on a surface of a blocking layer (see FIG. 3).

The photosensitive layer may be provided in a linear or dispersed shape, and preferably in a film shape.

The configurations of the photoelectric conversion element of the invention, other than the configurations specified in the invention, are not particularly limited, and known configurations related to the photoelectric conversion element and the solar cell can be employed. The respective layers constituting the photoelectric conversion element of the invention are designed according to the purpose, and may be formed into either a single layer or a multi-layer.

Hereinafter, preferred aspects of the photoelectric conversion element of the invention will be described.

In FIGS. 1 to 3, the same references indicate the same constituent elements (members).

FIGS. 1 and 2 show the size of fine particles which form the porous layer in an emphasized manner. These fine particles are preferably stuck (accumulated or firmly adhered) in a horizontal direction and in a vertical direction relative to the conductive support to form a porous structure.

In this description, when simply using the expression “photoelectric conversion element 10”, it means photoelectric conversion elements 10A, 10B, and 10C unless otherwise mentioned. This is also applied to the cases of “system 100”, “first electrode 1”, and “photosensitive layer 13”. When simply using the expression “hole transport layer 3”, it means hole transport layers 3A and 3B unless otherwise mentioned.

As a preferred aspect of the photoelectric conversion element of the invention, a photoelectric conversion element 10A shown in FIG. 1 can be exemplified. A system 100A shown in FIG. 1 is a system in which the photoelectric conversion element 10A is applied for use in a cell to make operation means M (for example, electric motor) work by an external circuit 6.

This photoelectric conversion element 10A has a first electrode 1A, a second electrode 2, and a hole transport layer 3A. The first electrode 1A has a conductive support 11 formed of a support 11a and a transparent electrode 11b, a porous layer 12, and a photosensitive layer 13A formed of a perovskite light absorber. It is preferable that a blocking layer 14 is provided on the transparent electrode 11b and a porous layer 12 is formed on the blocking layer 14.

A photoelectric conversion element 10B shown in FIG. 2 schematically shows a preferred aspect in which the photosensitive layer 13A of the photoelectric conversion element 10A shown in FIG. 1 is provided to have a large thickness. In this photoelectric conversion element 10B, a hole transport layer 3B is provided to have a small thickness. The photoelectric conversion element 10B is different from the photoelectric conversion element 10A shown in FIG. 1 in terms of the thicknesses of the photosensitive layer 13B and the hole transport layer 3B, but except for this, the photoelectric conversion element 10B has the same configuration as the photoelectric conversion element 10A.

A photoelectric conversion element 10C shown in FIG. 3 schematically shows another preferred aspect of the photoelectric conversion element of the invention. The photoelectric conversion element 10C is different from the photoelectric conversion element 10B shown in FIG. 2 in terms of the fact that no porous layer 12 is provided, but except for this, the photoelectric conversion element 10C has the same configuration as the photoelectric conversion element 10B. That is, in the photoelectric conversion element 10C, a photosensitive layer 13C is formed on the surface of the blocking layer 14.

In the invention, the system 100 applying the photoelectric conversion element 10 functions as a solar cell as follows.

That is, in the photoelectric conversion element 10, the light transmitted through the conductive support 11 or the second electrode 2 and entering the photosensitive layer 13 excites the light absorber. The excited light absorber has high-energy electrons, and the electrons reach the conductive support 11 from the photosensitive layer 13. At this time, the light absorber emitting the high-energy electrons becomes an oxidant. The electrons reaching the conductive support 11 return to the photosensitive layer 13 through the second electrode 2 and the hole transport layer 3 while working in the external circuit 6. The light absorber is reduced by the electrons returning to the photosensitive layer 13. The system 100 functions as a solar cell by repeating the excitation of the light absorber and the transfer of the electrons.

The flow of the electrons from the photosensitive layer 13 to the conductive support 11 varies with the presence or absence and the type of the porous layer 12, the type of the light absorber, and the like. When using a perovskite light absorber as the light absorber, electronic conduction occurs in which electrons move between perovskite compounds in the photoelectric conversion element 10. Accordingly, when providing the porous layer 12, the porous layer 12 can be formed of an insulator other than a conventional semiconductor. When the porous layer 12 is formed of a semiconductor, electronic conduction occurs in which electrons move in or between semiconductor fine particles of the porous layer 12. When the porous layer 12 is formed of an insulator, no electronic conduction occurs in the porous layer 12.

When the blocking layer 14 as one of the above-described other layers is formed of a conductor or a semiconductor, electronic conduction occurs in the blocking layer 14.

The photoelectric conversion element and the solar cell of the invention are not limited to the preferred aspects, and the configurations and the like of the respective aspects can be appropriately combined between the aspects without departing from the gist of the invention.

In the invention, except for the perovskite light absorber as a sensitizer, the materials and the members used in the photoelectric conversion element or the solar cell can be prepared through usual methods. For example, KR10-1172374B, J. Am. Chem. Soc., 2009, 131 (17), 6050-6051, and Science, 338, 643 (2012) can be referred to regarding a photoelectric conversion element or a solar cell using a perovskite light absorber. In addition, for example, JP2001-291534A, U.S. Pat. No. 4,927,721A, U.S. Pat. No. 4,684,537A, U.S. Pat. No. 5,084,365A, U.S. Pat. No. 5,350,644A, U.S. Pat. No. 5,463,057A, U.S. Pat. No. 5,525,440A, JP1995-249790A (JP-H7-249790A), JP2004-220974A, and JP2008-135197A can be referred to regarding a dye-sensitized solar cell.

Hereinafter, preferred aspects of main members and compounds of the photoelectric conversion element and the solar cell of the invention will be described.

<First Electrode 1>

The first electrode 1 has the conductive support 11 and the photosensitive layer 13, and functions as a working electrode in the photoelectric conversion element 10.

The first electrode 1 preferably has one or both of the porous layer 12 and the blocking layer 14, and more preferably has at least the blocking layer 14.

—Conductive Support 11—

The conductive support 11 is not particularly limited as long as it has conductive properties and can support the photosensitive layer 13 and the like. The conductive support is preferably a conductive support made of a conductive material such as a metal, or a conductive support 11 having a glass or plastic support 11a and a conductive film as a transparent electrode 11b formed on a surface of the support 11a.

Among these, a conductive support 11 in which a transparent electrode 11b is formed by coating a surface of a glass or plastic support 11a with a conductive metal oxide as shown in FIGS. 1 to 3 is more preferred. Examples of the plastic support 11a include transparent polymer films described in paragraph 0153 of JP2001-291534A. As the material which forms the support 11a, ceramics (JP2005-135902A) or a conductive resin (JP2001-160425A) can be used other than glass and plastic. As the metal oxide, a tin oxide (TO) is preferred, and an indium-tin oxide (tin-doped indium oxide; ITO) and a fluorine-doped tin oxide such as a tin oxide doped with fluorine (FTO) are particularly preferred. At this time, the amount of the metal oxide applied is preferably 0.1 g to 100 g per surface area of 1 m² of the support 11a. When using the conductive support 11, light preferably enters from the side of the support 11a.

The conductive support 11 is preferably substantially transparent. In the invention, the expression “substantially transparent” means that the transmittance of light (wavelength: 300 nm to 1200 nm) is 10% or greater, and the transmittance is preferably 50% or greater, and particularly preferably 80% or greater.

The thicknesses of the support 11a and the conductive support 11 are not particularly limited and are set to appropriate thicknesses. For example, the thicknesses are preferably 0.01 μm to 10 mm, more preferably 0.1 μm to 5 mm, and particularly preferably 0.3 μm to 4 mm.

When providing the transparent electrode 11b, the thickness of the transparent electrode 11b is not particularly limited. For example, the thickness is preferably 0.01 μm to 30 μm, more preferably 0.03 μm to 25 μm, and particularly preferably 0.05 μm to 20 μm.

The surface of the conductive support 11 or the support 11a may have a light management function. For example, an anti-reflection film described in JP2003-123859A, obtained by alternately laminating a high-refraction film and an oxide film having a low refractive index, may be provided on the surface of the conductive support 11 or the support 11a, or a light guide function described in JP2002-260746A may be imparted thereto.

—Blocking Layer 14—

In the invention, the blocking layer 14 is preferably provided on a surface of the transparent electrode 11b, that is, between the conductive support 11 and the porous layer 12 or the hole transport layer 3.

In the photoelectric conversion element and the solar cell, when the hole transport layer 3 and the transparent electrode 11b are brought into direct contact with each other, a reverse current is generated. The blocking layer 14 functions to prevent the reverse current. The blocking layer 14 is also called a short circuit prevention layer.

The material which forms the blocking layer 14 is not particularly limited as long as it is a material capable of serving the above-described function. However, the material is preferably a visible light transmissive substance having insulating properties with respect to the conductive support 11 (transparent electrode 11b). Specifically, the “substance having insulating properties with respect to the conductive support 11 (transparent electrode 11b)” indicates a compound (n-type semiconductor compound) having a conduction band energy level that is not lower than that of the material which forms the conductive support 11 (a metal oxide which forms the transparent electrode 11b) and is lower than those of the material which forms the porous layer 12 and the light absorber in a ground state.

Examples of the material which forms the blocking layer 14 include silicon oxide, magnesium oxide, aluminum oxide, calcium carbonate, polyvinyl alcohol, and polyurethane. In addition, the material may be a material which is usually used as a photoelectric conversion material, and examples thereof include titanium oxide, tin oxide, niobium oxide, and tungsten oxide. Among these, titanium oxide, tin oxide, magnesium oxide, aluminum oxide, and the like are preferred.

The thickness of the blocking layer 14 is preferably 0.001 μm to 10 μm, more preferably 0.005 μm to 1 μm, and particularly preferably 0.01 μm to 0.1 μm.

—Porous Layer 12—

In the invention, the porous layer 12 is preferably provided on the transparent electrode 11b. When the blocking layer 14 is provided, the porous layer 12 is formed on the blocking layer 14.

The porous layer 12 is a layer functioning as a foundation to carry the photosensitive layer 13 on the surface thereof. In the solar cell, in order to increase the light absorption efficiency, the surface area of at least a part which receives light such as solar light is preferably increased, and the entire surface area of the porous layer 12 is more preferably increased.

The porous layer 12 is preferably a fine particle layer with pores, which is formed by accumulating or firmly adhering fine particles of the material which forms the porous layer 12. The porous layer 12 may be a fine particle layer which is formed by accumulating two or more types of multi-fine particles. When the porous layer 12 is a fine particle layer with pores, the amount of the light absorber carried (adsorbed) can be increased.

The surface areas of the respective fine particles constituting the porous layer 12 are preferably increased to increase the surface area of the porous layer 12. In the invention, in a state in which the conductive support 11 or the like is coated with fine particles which form the porous layer 12, the surface area of the fine particles is preferably 10 or more times, and more preferably 100 or more times the projected area. The upper limit thereof is not particularly limited, but generally about 5000 times. The particle diameter of the fine particles which form the porous layer 12 is preferably 0.001 μm to 1 μm as primary particles in terms of the average particle diameter using a diameter when the projected area is converted into a circle. When the porous layer 12 is formed using a dispersion of fine particles, the average particle diameter of the fine particles is preferably 0.01 μm to 100 μm in terms of the average particle diameter of the dispersion.

The material which forms the porous layer 12 is not particularly limited in terms of the conductive properties. The material may be an insulator (insulating material), or a conductive material or semiconductor (semiconductive material).

As the material which forms the porous layer 12, a chalcogenide (for example, oxide, sulfide, selenide, and the like) of a metal, a compound having a perovskite crystal structure (except for light absorber to be described later), a silicon oxide (for example, silicon dioxide and zeolite), or a carbon nano-tube (including carbon nano-wire, carbon nano-rod, and the like) can be used.

The chalcogenide of a metal is not particularly limited, and preferred examples thereof include an oxide of titanium, tin, zinc, tungsten, zirconium, hafnium, strontium, indium, cerium, yttrium, lanthanum, vanadium, niobium, aluminum, or tantalum, cadmium sulfide, and cadmium selenide. Examples of the crystal structure of the chalcogenide of a metal include an anatase type, a brookite type, and a rutile type, and an anatase type and a brookite type are preferred.

The compound having a perovskite crystal structure is not particularly limited, and examples thereof include a transition metal oxide. Examples thereof include strontium titanate, calcium titanate, barium titanate, lead titanate, barium zirconate, barium stannate, lead zirconate, strontium zirconate, strontium tantalate, potassium niobate, bismuth ferrate, strontium barium titanate, barium lanthanum titanate, calcium titanate, sodium titanate, and bismuth titanate. Among these, strontium titanate, calcium titanate, and the like are preferred.

The carbon nano-tube has a shape in which a carbon film (graphene sheet) is rounded into a cylindrical shape. The carbon nano-tube is classified into a single-layer carbon nano-tube (SWCNT) in which one graphene sheet is wound into a cylindrical shape, a double-layer carbon nano-tube (DWCNT) in which two graphene sheets are concentrically wound, and a multi-layer carbon nano-tube (MWCNT) in which a plurality of graphene sheets are concentrically wound. As the porous layer 12, any carbon nano-tube can be used with no particular limits.

Among these, an oxide of titanium, tin, zinc, zirconium, aluminum, or silicon, or a carbon nano-tube is preferred, and a titanium oxide or an aluminum oxide is more preferred as the material which forms the porous layer 12.

The porous layer 12 may be formed of at least one or two or more of the above-described chalcogenide of a metal, compound having a perovskite crystal structure, oxide of silicon, and carbon nano-tube.

As will be described later, the material which forms the porous layer 12 is preferably used as fine particles. Regarding the material which forms the porous layer 12, a nano-tube, nano-wire, or nano-rod of a chalcogenide of a metal, a compound having a perovskite crystal structure, and an oxide of silicon may be used with fine particles of a chalcogenide of a metal, a compound having a perovskite crystal structure, an oxide of silicon, and a carbon nano-tube.

The thickness of the porous layer 12 is not particularly limited, but usually within a range of 0.1 μm to 100 μm. When the photoelectric conversion element is used as a solar cell, the thickness is preferably 0.1 μm to 50 μm and more preferably 0.3 μm to 30 μm.

The thickness of the porous layer 12 is specified by an average distance from the surface of the underlying layer on which the porous layer 12 is formed to the surface of the porous layer 12 along a linear direction intersecting at an angle of 90° relative to the surface of the conductive support 11 in a cross-section of the photoelectric conversion element 10. Here, the “surface of the underlying layer on which the porous layer 12 is formed” means an interface between the conductive support 11 and the porous layer 12. When other layers such as the blocking layer 14 are formed between the conductive support 11 and the porous layer 12, the above expression, “surface of the underlying layer on which the porous layer 12 is formed”, means an interface between the above other layers and the porous layer 12. In addition, the “surface of the porous layer 12” is, on a virtual straight line intersecting at an angle of 90° relative to the surface of the conductive support 11, a point of the porous layer 12 positioned closest to the side of the second electrode 2 from the conductive support 11 (intersection point between the virtual straight line and the outline of the porous layer 12). The “average distance” means an average of ten farthest distances, each of which is obtained by obtaining a farthest distance from the surface of the underlying layer to the surface of the porous layer 12 for each of ten parts obtained by equally dividing a specific observation region in a cross-section of the photoelectric conversion element 10 into ten along a direction (horizontal direction in FIGS. 1 to 3) horizontal to (parallel to) the surface of the conductive support 11. The thickness of the porous layer 12 can be measured by observing the cross-section of the photoelectric conversion element 10 with a scanning electron microscope (SEM).

Unless otherwise mentioned, thicknesses of other layers such as the blocking layer 14 can also be measured in the same manner.

—Photosensitive Layer (Light Absorption Layer) 13—

The photosensitive layer 13 is provided on the surface (when this surface has irregularities, interior surfaces thereof are included) of the porous layer 12 (photoelectric conversion elements 10A and 10B) or the blocking layer 14 (photoelectric conversion element 10C) with a perovskite compound (P) to be described later as a light absorber.

The photosensitive layer 13 may be a single layer or a lamination layer of two or more layers. When the photosensitive layer 13 has a lamination structure of two or more layers, layers formed of different light absorbers may be laminated, or an intermediate layer containing a hole transport material may be laminated between photosensitive layers.

The aspect in which the photosensitive layer 13 is on the conductive support 11 is as described above, and the photosensitive layer 13 is preferably provided on the porous layer 12 or the blocking layer 14 such that excited electrons flow to the conductive support 11. At this time, the photosensitive layer 13 may be provided on a part or the whole of the surface of the porous layer 12 or the blocking layer 14.

The thickness of the photosensitive layer 13 is appropriately set according to the aspect in which the photosensitive layer 13 is on the conductive support 11, and is not particularly limited. For example, the thickness of the photosensitive layer 13 (when the porous layer 12 is provided, a total thickness including the thickness of the porous layer 12) is preferably 0.1 μm to 100 μm, more preferably 0.1 μm to 50 μm, and particularly preferably 0.3 μm to 30 μm. The thickness of the photosensitive layer 13 can be measured in the same manner as in the case of the thickness of the porous layer 12. When the photosensitive layer 13 has a thin film shape, a distance from an interface between the photosensitive layer 13 and the porous layer 12 to an interface between the photosensitive layer 13 and the hole transport layer 3 along a direction perpendicular to the surface of the porous layer 12 is set as the thickness of the photosensitive layer 13.

The photoelectric conversion element 10B shown in FIG. 2 has a photosensitive layer 13B having a larger thickness than the photosensitive layer 13A of the photoelectric conversion element 10A shown in FIG. 1. In this case, the perovskite compound as a light absorber may be a hole transport material as in the case of the above-described compound having a perovskite crystal structure as a material which forms the porous layer 12.

(Light Absorber)

The photosensitive layer 13 contains, as a light absorber, at least one of compound (P) having a perovskite crystal structure represented by the following Formula (I).

A cationic group A, a metal atom M, and an anionic atom X of the perovskite compound (P) represented by the following Formula (I) exist as constituent ions of a cation (for convenience, may be referred to as cation A), a metal cation (for convenience, may be referred to as cation M), and an anion (for convenience, may be referred to as anion X), respectively, in the perovskite crystal structure.

In the invention, the cationic group is a group having such properties as to be a cation in the perovskite crystal structure, and the anionic atom is an atom having such properties as to be an anion in the perovskite crystal structure.

Accordingly, the perovskite compound (P) used in the invention has a perovskite crystal structure having cations, metal cations, and anions as constituent ions, and is not particularly limited as long as it is a compound represented by the following Formula (I).

Aₐ(M^{A1}₍₁₋ₙ₎M^{A2}ₙ)_{mA}Xₓ Formula (I):

In the formula, A represents a cationic group represented by the following Formula (A). M^{A1} and M^{A2} represent metal atoms different from each other. n represents a number satisfying 0≦n≦0.5. X represents an anionic atom.

In Formula (I), a represents 1 or 2, and mA represents 1. a, mA, and x satisfy a+2 mA=x. That is, when a is 1, x is 3, and when a is 2, x is 4.

R^{A}—NH₃ Formula (A):

In the formula, R^{A} represents an alkyl group, a cycloalkyl group, an alkenyl group, an alkynyl group, an aryl group, a heteroaryl group, or a group represented by the following Formula (1), which may have a substituent. The alkyl group has a substituent when n represents a number of 0 to less than 0.01.

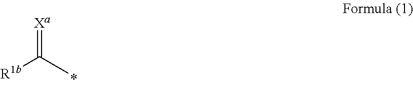

In the formula, X^{a} represents NR^{1c}, an oxygen atom, or a sulfur atom. Each of R^{1b} and R^{1c} independently represents a hydrogen atom or a substituent. * represents a bonding position with the N atom of Formula (A).

The perovskite compound represented by Formula (I) may be a perovskite compound which contains two of metal atoms at the above-described ratio, a perovskite compound in which an ammonium cation is substituted with an organic cation consisting of a cationic group represented by Formula (A), or a perovskite compound which contains two of metal atoms at the above-described ratio and in which an ammonium cation is substituted with an organic cation consisting of a cationic group represented by Formula (A).

The reason why the fluctuation in the photoelectric conversion efficiency can be reduced when the photosensitive layer 13 contains at least one of perovskite compound (P) as the light absorber is not yet clear, but assumed as follows. That is, the interaction between R^{A} in the cation A in the perovskite compound (P) as the light absorber and the hole transport material increases, and as a result, the interaction between the photosensitive layer 13 containing the perovskite compound (P) and the hole transport material also increases and the adhesion between the photosensitive layer 13 and the hole transport material is thus thought to be improved. In addition, the electronic interaction between the perovskite compound (P) and the hole transport material also increases, and thus stabilization in the transfer of electrons is thought to be obtained.

The metal atoms M^{A1} and M^{A2} are metal atoms different from each other. The metal atoms M^{A1} and M^{A2} are metal atoms which form metal cations constituting the perovskite crystal structure. Accordingly, the metal atoms M^{A1} and M^{A2} are not particularly limited as long as these are metal atoms which form metal cations to have the perovskite crystal structure.

Examples of such metal atoms include metal atoms of calcium (Ca), strontium (Sr), cadmium (Cd), copper (Cu), nickel (Ni), manganese (Mn), iron (Fe), cobalt (Co), palladium (Pd), germanium (Ge), tin (Sn), lead (Pb), ytterbium (Yb), europium (Eu), and indium (In). Among these, each of the metal atoms M^{A1} and M^{A2} is preferably selected from a Pb atom and a Sn atom. That is, it is preferable that one of M^{A1} and M^{A2} is a Pb atom and the other is a Sn atom. It is more preferable that M^{A1} is a Pb atom and M^{A2} is a Sn atom from the viewpoint of reducing the fluctuation in the photoelectric conversion efficiency.

n in Formula (I), that is, a molar content ratio n of the metal atom M^{A2} with respect to a total of the metal atoms M^{A1} and M^{A2} is a number satisfying 0≦n≦0.5. n is preferably 0.05 to 0.20 from the viewpoint of reducing the fluctuation in the photoelectric conversion efficiency.

The cationic group A in Formula (I) is a group which forms the cation A constituting the perovskite crystal structure. Accordingly, the cationic group A is not particularly limited as long as it is a group which forms the cation A and can constitute the perovskite crystal structure.

In the invention, the cationic group A is preferably an ammonium cationic group produced by bonding R^{A} and NH₃ in Formula (A). When this ammonium cationic group has a resonance structure, the cationic group A includes a cationic group having a resonance structure in addition to the ammonium cationic group. For example, when X^{a} is NH (R^{1c} is a hydrogen atom) in the group represented by Formula (1), the cationic group A also includes, in addition to the ammonium cationic group produced by bonding the group represented by Formula (1) and NH₃, an amidinium cationic group which is one of resonance structures of the ammonium cationic group. A cation represented by the following Formula (A^{am}) can be exemplified as an amidinium cation consisting of the amidinium cationic group. In this description, the cation represented by the following Formula (A^{am}) may be expressed as “R^{1b}C(═NH)—NH₃” for convenience.

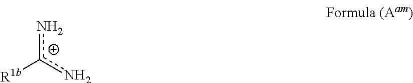

The cationic group A in Formula (I) is a cationic group which is represented by Formula (A) and contains an organic group R^{A}. The organic group R^{A} is an alkyl group (having a substituent when n represents a number satisfying 0≦n<0.01), a cycloalkyl group, an alkenyl group, alkynyl group, an aryl group, a heteroaryl group, or a group represented by Formula (1), which may have a substituent.

The alkyl group includes an alkyl group which is not substituted (unsubstituted alkyl group) and an alkyl group having a substituent (substituted alkyl group), and one or both of the alkyl groups are selected according to the molar content ratio n of the metal atom M^{A2}. Specifically, when n is a number satisfying 0≦n<0.01, the alkyl group is a substituted alkyl group, and when n is a number satisfying 0.01≦n≦0.5, the alkyl group is an unsubstituted alkyl group or a substituted alkyl group.

The unsubstituted alkyl group may be a linear alkyl group, and is not particularly limited. However, the unsubstituted alkyl group has preferably 1 to 18 carbon atoms, and more preferably 1 to 3 carbon atoms. Examples of such an unsubstituted alkyl group include methyl, ethyl, n-propyl, isopropyl, n-butyl, t-butyl, n-pentyl, n-hexyl, and n-decyl.

The substituted alkyl group may be a group in which the unsubstituted alkyl group has a substituent selected from a substituent group T to be described later. The substituted alkyl group may be a linear alkyl group or a branched alkyl group having an alkyl group as a substituent. The unsubstituted alkyl group before the substitution of the substituted alkyl group with a substituent is synonymous with the above-described unsubstituted alkyl group, and is an alkyl group having preferably 1 to 4 carbon atoms, more preferably 1 to 3 carbon atoms, and even more preferably 1 or 2 carbon atoms.

The cycloalkyl group is preferably a cycloalkyl group having 3 to 8 carbon atoms, and examples thereof include cyclopropyl, cyclopentyl, and cyclohexyl.

The alkenyl group is linear, and is preferably an alkenyl group having 2 to 18 carbon atoms. Examples thereof include ethenyl, allyl, butenyl, and hexenyl. The alkenyl group may be a branched alkenyl group having an alkyl group as a substituent. Examples of the branched alkenyl group include 1-methyl-2-propenyl.

The alkynyl group is preferably an alkynyl group having 2 to 18 carbon atoms, and examples thereof include ethynyl, butynyl, and hexynyl.

The aryl group is preferably an aryl group having 6 to 14 carbon atoms, and examples thereof include phenyl.

The heteroaryl group includes a group formed only of an aromatic hetero ring and a group formed of a condensed hetero ring obtained by condensing an aromatic hetero ring with other rings such as an aromatic ring, an aliphatic ring, and a hetero ring.

A nitrogen atom, an oxygen atom, and a sulfur atom are preferred as a ring-constituent hetero atom constituting the aromatic hetero ring. The number of membered rings of the aromatic hetero ring is preferably 5 or 6.

Examples of the five-membered aromatic hetero ring and the condensed hetero ring including a five-membered aromatic hetero ring include ring groups of a pyrrole ring, an imidazole ring, a pyrazole ring, an oxazole ring, a thiazole ring, a triazole ring, a furan ring, a thiophene ring, a benzoimidazole ring, a benzoxazole ring, a benzothiazole ring, an indoline ring, and an indazole ring. Examples of the six-membered aromatic hetero ring and the condensed hetero ring including a six-membered aromatic hetero ring include ring groups of a pyridine ring, a pyrimidine ring, a pyrazine ring, a triazine ring, a quinoline ring, and a quinazoline ring.

In the group represented by Formula (1), X^{a} represents NR^{1c}, an oxygen atom, or a sulfur atom, and is preferably NR^{1c}. Here, R^{1c} is preferably a hydrogen atom, an alkyl group, a cycloalkyl group, an alkenyl group, an alkynyl group, an aryl group, or a heteroaryl group, and more preferably a hydrogen atom.

R^{1b} represents a hydrogen atom or a substituent, and is preferably a hydrogen atom. Examples of the substituent which can be taken by R^{1b} include a hydrogen atom, an alkyl group, a cycloalkyl group, an alkenyl group, an alkynyl group, an aryl group, and a heteroaryl group.

The alkyl group, the cycloalkyl group, the alkenyl group, the alkynyl group, the aryl group, and the heteroaryl group, which can be taken by R^{1b} and R^{1c}, are synonymous with the groups of R^{A}, and preferred groups are also the same as those of R^{A}.

Examples of the group represented by Formula (1) include formimidoyl (HC(═NH)—), acetoimidoyl (CH₃C(═NH)—), and propionimidoyl (CH₃CH₂C(═NH)—). Among these, formimidoyl is preferred.

The groups of the organic group R^{A} include unsubstituted groups and groups having a substituent. A substituent T, that each group forming the cation A may have, is not particularly limited, but is preferably at least one selected from the group consisting of an alkyl group, a cycloalkyl group, an alkenyl group, an alkynyl group, an alkoxy group, an alkylthio group, a mercapto group, an aryloxy group, an amino group, a carboxy group, an acyl group, an alkoxycarbonyl group, an aryloxycarbonyl group, an alkyl carbonyloxy group, an aryl carbonyloxy group, a halogen atom, a cyano group, an aryl group, and a heteroaryl group. Here, “at least one selected from the group” includes one group selected from the above-described group and a group obtained by combining at least two groups selected from the above-described group (such as a group in which one group selected from the above-described group is substituted with one group selected from the above-described group).

The substituent T is preferably at least one selected from the group consisting of an alkyl group, a halogen atom, a cyano group, and an aryl group, and more preferably a halogen atom or an alkyl group substituted with a halogen atom.

Among the substituents T, the alkyl group, the cycloalkyl group, the alkenyl group, the alkynyl group, the aryl group, and the heteroaryl group are synonymous with the alkyl group, the cycloalkyl group, the alkenyl group, the alkynyl group, the aryl group, and the heteroaryl group of R^{A}, and preferred groups are also the same as those of R^{A}.

The alkoxy group and the alkylthio group are preferably alkyl groups in which an alkyl part is the same as the alkyl group of R^{A}.

The amino group is preferably an unsubstituted amino group, a mono-substituted amino group, or a disubstituted amino group. The substituent of the mono-substituted amino group and the disubstituted amino group is preferably an alkyl group (preferably synonymous with the alkyl group of R^{A}) or an aryl group (preferably synonymous with the aryl group of R^{A}).

The acyl group, the alkoxycarbonyl group, and the alkyl carbonyloxy group preferably have an alkyl part which is the same as the alkyl group of R^{A}.

The aryloxycarbonyl group, the aryloxy group, and the aryl carbonyloxy group preferably have an aryl group which is the same as the aryl group of R^{A} or a heteroaryl group.

The halogen atom is not particularly limited. However, a fluorine atom, a chlorine atom, a bromine atom, or an iodine atom is preferred, and a fluorine atom, a chlorine atom, or a bromine atom is more preferred.

In the substituent T, the group obtained by combination is not particularly limited as long as it is a group obtained by combining at least two of the above-described substituents, and examples thereof include a group obtained by combining an alkyl group and an alkynyl group, a group obtained by combining an alkyl group and a halogen atom (preferably an alkyl group substituted with a halogen atom), a cyanoalkyl group, and an aminoalkyl group.

The alkyl group substituted with a halogen atom may be a group in which at least one hydrogen atom of the alkyl group in the description of R^{A} is substituted with the halogen atom, and is preferably an alkyl group substituted with a fluorine atom. Examples thereof include fluoromethyl, trifluoromethyl, and 1,1,1-trifluoroethyl.

When the groups of R^{A} have a plurality of substituents T, the respective substituents T may be the same as or different from each other.

The following r-1 to r-34 are shown as specific examples of R^{A} in Formula (A), but the invention is not limited thereto.

r-1, r-2, and r-5 are specific examples of R^{A1} in Formula (A1) and the others are specific examples of R^{A2} in Formula (A2).

In the following description, “*” represents a bond, “Me” indicates a methyl group, and “Et” indicates an ethyl group.

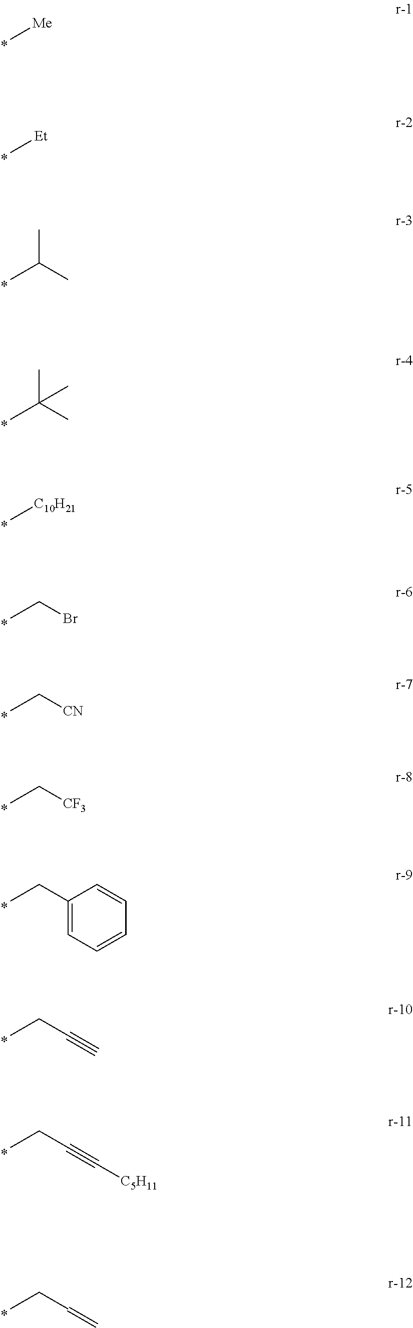

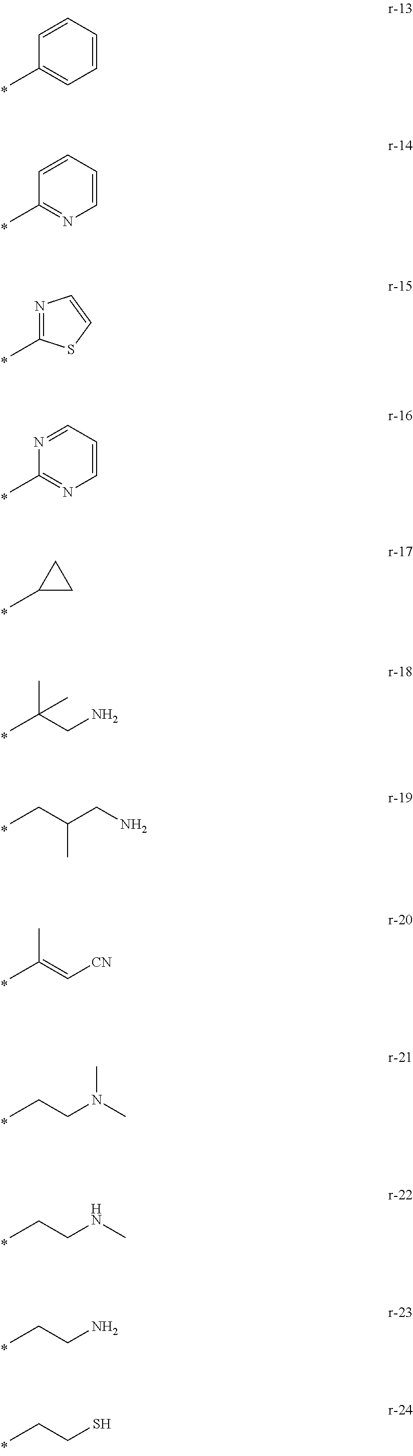

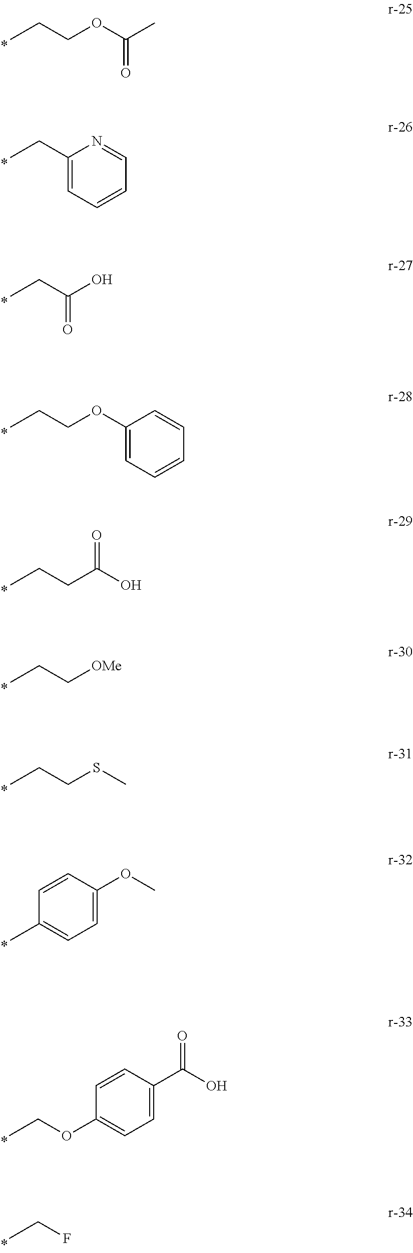

The anionic atom X in Formula (I) is an atom which forms an anion X of an atom constituting a perovskite crystal structure. Accordingly, the anionic atom X is not particularly limited as long as it is an atom which forms an anion and can constitute the perovskite crystal structure.

In the perovskite compound (P), the anionic atom is preferably a halogen atom, and examples thereof include a fluorine atom, a chlorine atom, a bromine atom, and an iodine atom.

The anionic atoms X may be one of atoms, but are preferably two or more of atoms from the viewpoint of reducing the fluctuation in the photoelectric conversion efficiency. When the anionic atoms X are two or more of atoms, the anionic atom X is preferably an anionic atom represented by the following Formula (X). When a in Formula (I) is 1, the anionic atom X is preferably represented by the following Formula (X1), and when a in Formula (I) is 2, the anionic atom X is preferably represented by the following Formula (X2).

X^{A1}₍ₓ₋ₘ₎X^{A2}ₘ Formula (X):

X^{A1}₍₃₋ₘ₁₎X^{A2}ₘ₁ Formula (X1):

X^{A1}₍₄₋ₘ₂₎X^{A2}ₘ₂ Formula (X2):

In the formulae, X^{A1} and X^{A2} represent anionic atoms X different from each other. It is preferable that X^{A1} and X^{A2} are halogen atoms different from each other, and it is more preferable that one of X^{A1} and X^{A2} is an iodine atom and the other is a chlorine atom or a bromine atom from the viewpoint of reducing the fluctuation in the photoelectric conversion efficiency.

x is synonymous with x of Formula (I). When a in Formula (I) is 1, x is 3, and when a in Formula (I) is 2, x is 4. m is preferably 0.01 to (x−0.01), more preferably 0.1 to 1.4, and even more preferably 0.5 to 1.0.

In Formula (X1), m1 is preferably 0.01 to 2.99, more preferably 0.1 to 1.4, and even more preferably 0.5 to 1.0.

In Formula (X2), m2 is preferably 0.01 to 3.99, more preferably 0.1 to 1.4, and even more preferably 0.5 to 1.0.

The perovskite compound (P) represented by Formula (I) is a perovskite compound (P^{A}) represented by the following Formula (IA) when a is 1, and the perovskite compound (P) represented by Formula (I) is a perovskite compound (P^{B}) represented by the following Formula (IB) when a is 2.

A(M^{A1}₍₁₋ₙ₎M^{A2}ₙ)X₃ Formula (IA):

A₂(M^{A1}₍₁₋ₙ₎M^{A2}ₙ)X₄ Formula (IB):

In Formulae (IA) and (IB), A represents a cationic group A, and is synonymous with the cationic group A of Formula (I). Preferred examples thereof are also the same as those of the cationic group A.

In Formulae (IA) and (IB), M^{A1} and M^{A2} represent metal atoms different from each other, and are synonymous with the metal atoms M^{A1} and M^{A2} of Formula (I). Preferred examples thereof are also the same as those of M^{A1} and M^{A2} of Formula (I).

In Formulae (IA) and (IB), X represents an anionic atom, and is synonymous with the anionic atom X of Formula (I). Preferred examples thereof are also the same as those of the anionic atom X of Formula (I).

Here, the perovskite crystal structure will be described.

As described above, the perovskite crystal structure contains the cation A of the cationic group A, the metal cation M of the metal atoms M^{A1} and M^{A2}, and the anion X of the anionic atom X as constituent ions.

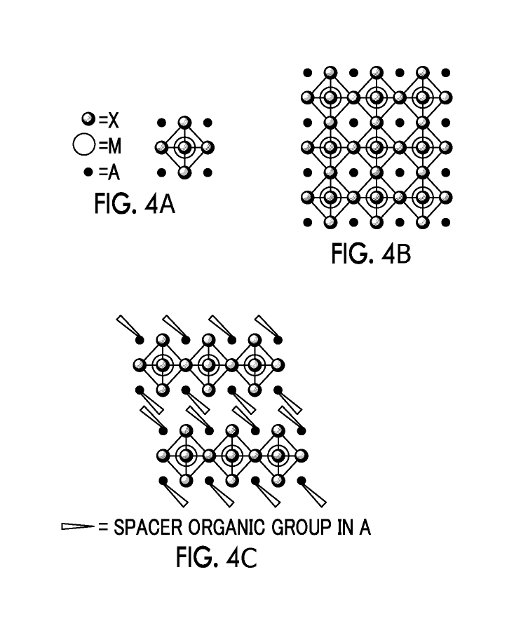

FIG. 4A is a diagram showing a fundamental unit lattice of the perovskite crystal structure, and FIG. 4B is a diagram showing a structure in which fundamental unit lattices are three-dimensionally continuous to each other in the perovskite crystal structure. FIG. 4C is a diagram showing a layered structure in which an inorganic layer and an organic layer are alternately laminated in the perovskite crystal structure.

The perovskite compound (P^{A}) represented by Formula (IA) has a cubic fundamental unit lattice in which, as shown in FIG. 4A, a cation A is disposed at each apex, a metal cation M (cation of either of M^{A1} and M^{A2}) is disposed at a body center, and an anion X is disposed at each face center of the cubic having the metal cation M as a center. In addition, the perovskite compound (P^{A}) has a structure in which, as shown in FIG. 4B, one fundamental unit lattice shares a cation A and an anion X with each of other adjacent 26 fundamental unit lattices (surrounding the circumference) and fundamental unit lattices are three-dimensionally continuous to each other.

The perovskite compound (P^{B}) represented by Formula (TB) is the same as the perovskite compound (P^{A}) represented by Formula (IA) in terms of the fact that a MX₆ octahedron formed of a metal cation M (cation of either of M^{A1} and M^{A2}) and an anion X is provided, but is different therefrom in terms of the fundamental unit lattices and the arrangement form thereof. That is, the perovskite compound (P^{B}) represented by Formula (TB) has a layered structure in which, as shown in FIG. 4C, an inorganic layer formed by arranging MX₆ octahedrons two-dimensionally (in a plane shape) in a layer and an organic layer formed by inserting a cation A between inorganic layers are alternately laminated.

In such a layered structure, the fundamental unit lattices share cations A and anions X with other adjacent fundamental unit lattices in the surface of the same layer. The fundamental unit lattices do not share cations A and anions X in a different layer. This layered structure is a two-dimensional layered structure in which the inorganic layer is divided by the organic group of the cation A. As shown in FIG. 4C, the organic group in the cation A functions as a spacer organic group between the inorganic layers.

Regarding the perovskite compound having a layered structure, for example, New. J. Chem., 2008, 32, 1736 can be referred to.

The crystal structure of the perovskite compound is determined according to the cation A (cationic group A). For example, when the cation A is a cation of a cationic group having an organic group R^{A} having one carbon atom, the perovskite compound is represented by Formula (IA) and is likely to have a cubic crystal structure. Examples of such a cation A include cations of CH₃—NH₃ and H—C(═NH)—NH₃ (when R^{1b} and R^{1c} are hydrogen atoms) among groups represented by Formula (1).

When the cation A is a cation of a cationic group having an organic group R^{A} having two or more carbon atoms, the perovskite compound is represented by Formula (TB) and is likely to have a layered crystal structure. Examples of such a cation A include a cation of a cationic group A having an alkyl group, a cycloalkyl group, an alkenyl group, alkynyl group, an aryl group, a heteroaryl group, or a group represented by Formula (1) (when R^{1b} and R^{1c} are substituents), which have been described as the organic group R^{A} and have two or more carbon atoms.

The perovskite compound (P) used in the invention can be classified into the following perovskite compounds (P¹) and (P²) when focusing on the organic group R^{A}.

The perovskite compound (P¹) has, as the cationic group A, a cationic group A¹ represented by the following Formula (A¹) when n represents a number satisfying 0.01≦n≦0.5 in Formula (I). That is, the perovskite compound (P¹) is represented by the following Formula (I¹).

A¹ₐ(M^{A1}₍₁₋ₙ₁₎M^{A2}ₙ₁)_{mA}Xₓ Formula (I¹):

In the formula, A¹ represents a cationic group represented by the following Formula (A¹).

R^{A1}—NH₃ Formula (A¹):

In the formula, R^{A1} represents an unsubstituted alkyl group, and is synonymous with unsubstituted alkyl group of Formula (A). Preferred examples thereof are also the same as those of the unsubstituted alkyl group of Formula (A).

In Formula (I¹), M^{A1} and M^{A2} represent metal atoms different from each other, and are synonymous with M^{A1} and M^{A2} of Formula (I). Preferred examples thereof are also the same as those of M^{A1} and M^{A2} of Formula (I).

In Formula (I¹), n1 represents a number satisfying 0.01≦n1≦0.5, and a preferred range thereof is the same as the preferred range of n of Formula (I).

In Formula (I¹), X represents an anionic atom, and is synonymous with the anionic atom X of Formula (I). Preferred examples thereof are also the same as those of the anionic atom X of Formula (I).

In Formula (I¹), a, mA, and x are synonymous with a, mA, and x of Formula (I).

Furthermore, this perovskite compound (P¹) is classified into a perovskite compound (P^{A1}) represented by the following Formula (IA¹) and a perovskite compound (P^{B1}) represented by the following Formula (IB¹) when focusing on a of Formula (I).

(R^{A1}—NH₃)(M^{A1}₍₁₋ₙ₁₎M^{A2}ₙ₁)X₃ Formula (IA¹)

(R^{A1}—NH₃)₂(M^{A1}₍₁₋ₙ₁₎M^{A2}ₙ₁)X₄ Formula (IB¹)

In Formulae (IA¹) and (IB¹), R^{A1} represents an unsubstituted alkyl group, and is synonymous with R^{A1} of Formula (A¹). M^{A1}, M^{A2}, n1, and X are synonymous with M^{A1}, M^{A2}, n1, and X of Formula (I¹), and preferred examples thereof are also the same as those of M^{A1}, M^{A2}, n1, and X of Formula (I¹).

The perovskite compound (P²) has, as the cationic group A, a cationic group A² represented by the following Formula (A²) when n represents a number satisfying 0≦n≦0.5 in Formula (I). That is, the perovskite compound (P²) is represented by the following Formula (I²).

A²ₐ(M^{A1}₍₁₋ₙ₂₎M^{A2}ₙ₂)_{mA}Xₓ Formula (I²):

In Formula (I²), A² represents a cationic group represented by the following Formula (A²).

R^{A2}—NH₃ Formula (A²):

In Formula (A²), R^{A2} represents an alkyl group having a substituent, or a cycloalkyl group, an alkenyl group, an alkynyl group, an aryl group, a heteroaryl group, or a group represented by Formula (1), which may have a substituent. The groups of R^{A2} are synonymous with the groups corresponding to R^{A} of Formula (A), and preferred examples thereof are also the same as those of R^{A} of Formula (A). R^{A2} is preferably an alkyl group having a substituent, an aryl group, or a heteroaryl group, and more preferably an alkyl group having a substituent from the viewpoint of reducing the fluctuation in the photoelectric conversion efficiency.

In Formula (I²), M^{A1} and M^{A2} represent metal atoms different from each other, and are synonymous with M^{A1} and M^{A2} of Formula (I). Preferred examples thereof are also the same as those of M^{A1} and M^{A2} of Formula (I).

In Formula (I²), n2 represents a number satisfying 0≦n≦0.5, and a preferred range thereof is the same as the preferred range of n of Formula (I).

In Formula (I²), X represents an anionic atom, and is synonymous with the anionic atom X of Formula (I). Preferred examples thereof are also the same as those of the anionic atom X of Formula (I).

In Formula (I²), a, mA, and x are synonymous with a, mA, and x of Formula (I).

Furthermore, this perovskite compound (P²) is classified into a perovskite compound (P^{A2}) represented by the following Formula (IA²) and a perovskite compound (P^{B2}) represented by the following Formula (IB²) when focusing on a of Formula (I).

(R^{A2}—NH₃)(M^{A1}₍₁₋ₙ₂₎M^{A2}ₙ₂)Xhd 3 Formula (IA²):

(R^{A2}—NH₃)₂(M^{A1}₍₁₋ₙ₂₎M^{A2}ₙ₂)Xhd 4 Formula (IB²):

In Formulae (IA²) and (IB²), R^{A2} represents an alkyl group having a substituent, or a cycloalkyl group, an alkenyl group, an alkynyl group, an aryl group, a heteroaryl group, or a group represented by Formula (1), which may have a substituent. R^{A2} is synonymous with R^{A2} of Formula (A²), and preferred examples thereof are also the same as those of R^{A2} of Formula (A²).

In Formula (IA²) and (IB²), M^{A1}, M^{A2}, n2, and X are synonymous with M^{A1}, M^{A2}, n2, and X of Formula (I²), and preferred examples thereof are also the same as those of M^{A1}, M^{A2}, n2, and X of Formula (I²).

In the invention, the light absorber may contain at least one of perovskite compound (P), or may contain two or more of perovskite compounds (P).

The light absorber may contain either the perovskite compound (P^{A}) or the perovskite compound (P^{B}), or may contain both of them. Here, the perovskite compound (P^{A}) may be either the perovskite compound (P^{A1}) or the perovskite compound (P^{A2}), or may be a mixture thereof. In addition, the perovskite compound (P^{B}) may be either the perovskite compound (P^{B1}) or the perovskite compound (P^{B2}), or may be a mixture thereof.

Accordingly, in the invention, at least one of perovskite compound (P) may be contained as the light absorber, and there is no need to strictly and clearly distinguish the compound according to the composition formula, molecular formula, crystal structure, and the like.

The perovskite compound (P) used in the invention can be synthesized from MX₂ and AX (for example, R^{A1}—NH₃X or R^{A2}—NH₃X) according to the method described in J. Am. Chem. Soc., 2009, 131 (17), 6050-6051. Akihiro Kojima, Kenjiro Teshima, Yasuo Shirai, and Tsutomu Miyasaka, “Organometal Halide Perovskites as Visible-Light Sensitizers for Photovoltaic Cells” and J. Am. Chem. Soc., 2009, 131 (17), 6050-6051 can also be exemplified.

In these synthesis methods, a molar ratio between MX₂ and AX is adjusted according to the above-described n (n1 and n2) and m.

The perovskite light absorber may be used in such an amount as to cover at least a part of a light incident surface among the surfaces of the porous layer 12 or the blocking layer 14, and is preferably used in such an amount as to cover the entire light incident surface.

<Hole Transport Layer 3>

The hole transport layer 3 has a function to replenish electrons to an oxidant of the light absorber, and is preferably a solid-state layer. The hole transport layer 3 is preferably provided between the photosensitive layer 13 of the first electrode 1 and the second electrode 2.

The hole transport material which forms the hole transport layer 3 is not particularly limited, but examples thereof include inorganic materials such as CuI, CuNCS and organic hole transport materials described in paragraphs 0209 to 0212 of JP2001-291534A. Preferable examples of the organic hole transport material include conductive polymers such as polythiophene, polyaniline, polypyrrole, and polysilane, a Spiro compound in which two rings share a central atom such as C and Si having a tetrahedral structure, an aromatic amine compound such as triarylamine, a triphenylene compound, a nitrogen-containing heterocyclic compound, and a liquid crystal cyano compound.

The hole transport material is preferably a solid-state organic hole transport material which can be applied in a solution state, and specific examples thereof include 2,2′,7,7′-tetrakis-(N,N-di-p-methoxyphenylamine)-9,9-spirobifluorene (also referred to as Spiro-OMeTAD), poly(3-hexylthiophene-2,5-diyl), 4-(diethylamino)benzaldehyde diphenyl hydrazone, and polyethylenedioxythiophene (PEDOT).

The thickness of the hole transport layer 3 is not particularly limited, but is preferably 50 μm or less, more preferably 1 nm to 10 μm, even more preferably 5 nm to 5 μm, and particularly preferably 10 nm to 1 μm. The thickness of the hole transport layer 3 corresponds to an average distance between the second electrode 2 and the surface of the porous layer 12 or the surface of the photosensitive layer 13. This thickness can be measured in the same manner as in the case of the thickness of the porous layer 12 by observing a cross-section of the photoelectric conversion element 10 using a scanning electron microscope (SEM) or the like.

In the invention, the total thickness of the porous layer 12, the photosensitive layer 13, and the hole transport layer 3 is not particularly limited, but is preferably 0.1 μm to 200 μm, more preferably 0.5 μm to 50 μm, and even more preferably 0.5 μm to 5 μm.

Here, the thickness of the photosensitive layer 13 (total thickness including the thickness of the porous layer 12) and the total thickness of the porous layer 12, the photosensitive layer 13, and the hole transport layer 3 can be measured in the same manner as in the case of the thickness of the porous layer 12.

<Second Electrode 2>

The second layer 2 functions as a cathode in a solar cell. The second electrode 2 is not particularly limited as long as it has conductive properties, and generally may have the same configuration as the conductive support 11. The support 11a is not essentially required when a sufficient strength is kept.

As the structure of the second electrode 2, a structure having a high current collection effect is preferred. In order to allow light to reach the photosensitive layer 13, at least one of the conductive support 11 and the second electrode 2 should be substantially transparent. In the solar cell of the invention, it is preferable that the conductive support 11 is transparent and solar light is made incident from the side of the support 11a. In this case, it is more preferable that the second electrode 2 has light reflection properties.

Examples of the material which forms the second electrode 2 include metals such as platinum (Pt), gold (Au), nickel (Ni), copper (Cu), silver (Ag), indium (In), ruthenium (Ru), palladium (Pd), rhodium (Rh), iridium (Ir), and osmium (Os), the above-described conductive metal oxides, and carbon materials. The carbon materials may be conductive materials formed by bonding carbon atoms to each other, and examples thereof include fullerene, carbon nano-tube, graphite, and graphene.

The second electrode 2 is preferably glass or plastic having a thin film (including thin film formed by deposition) of a metal or a conductive metal oxide, and particularly preferably glass having a gold or platinum thin film or glass on which platinum is deposited.

The thickness of the second electrode 2 is not particularly limited, and is preferably 0.01 μm to 100 μm, more preferably 0.01 μm to 10 μm, and particularly preferably 0.01 μm to 1 μm.

<Other Configurations>

In the invention, in order to prevent the contact between the first electrode 1 and the second electrode 2, a spacer or a separator can also be used in place of or together with the blocking layer 14.

In addition, a hole blocking layer may be provided between the second electrode 2 and the hole transport layer 3.

<<Solar Cell>>

For example, as shown in FIGS. 1 to 3, the solar cell of the invention is configured such that the photoelectric conversion element of the invention is allowed to work with respect to the external circuit 6. As the external circuit connected to the first electrode 1 (conductive support 11) and the second electrode 2, a known external circuit can be used with no particular limits.

Side surfaces of the solar cell of the invention are preferably sealed with a polymer, an adhesive, or the like in order to prevent deterioration and transpiration of the constituent materials.

The solar cell having the photoelectric conversion element of the invention applied thereto is not particularly limited, and examples thereof include solar cells described in KR10-1172374B, J. Am. Chem. Soc., 2009, 131 (17), 6050-6051, and Science, 338, 643 (2012).

As described above, the photoelectric conversion element and the perovskite-sensitized solar cell of the invention have a photosensitive layer containing the compound (P) having a perovskite crystal structure, and the difference in the photoelectric conversion efficiency between individual cells is small, whereby stable cell performance is exhibited.

<<Method of Manufacturing Photoelectric Conversion Element and Solar Cell>>

The photoelectric conversion element and the solar cell of the invention can be manufactured according to known manufacturing methods such as methods described in KR10-1172374B, J. Am. Chem. Soc., 2009, 131 (17), 6050-6051, and Science, 338, 643 (2012).

Hereinafter, a method of manufacturing the photoelectric conversion element and the solar cell of the invention will be simply described.

At least one of the blocking layer 14 and the porous layer 12 is formed on a surface of the conductive support 11, if desired.

The blocking layer 14 can be formed through, for example, a method including: applying a dispersion containing the above-described insulating substance or its precursor compound to the surface of the conductive support 11; and performing baking, a spray pyrolysis method, or the like.

The material which forms the porous layer 12 is preferably used as fine particles, and more preferably as a dispersion containing fine particles.

The method of forming the porous layer 12 is not particularly limited, but examples thereof include a wet method, a dry method, and other methods (for example, method described in Chemical Review, vol. 110, p. 6595 (2010)). In these methods, baking is preferably performed for 10 minutes to 10 hours at a temperature of 100° C. to 800° C. after application of a dispersion (paste) to the surface of the conductive support 11 or the surface of the blocking layer 14. Accordingly, fine particles can be firmly adhered to each other.

When the baking is performed more than once, the temperature for baking other than final baking (temperature for baking other than final baking) may be lower than the temperature for final baking (final baking temperature). For example, when a titanium oxide paste is used, the temperature for baking other than final baking can be set within a range of 50° C. to 300° C. In addition, the final baking temperature can be set to be higher than the temperature for baking other than final baking within a range of 100° C. to 600° C. When a glass support is used as the support 11a, the baking temperature is preferably 60° C. to 500° C.

The amount of the porous material applied when forming the porous layer 12 is appropriately set according to the thickness of the porous layer 12 to be formed, the number of times of application, and the like, and is not particularly limited. The amount of the porous material applied per surface area of 1 m² of the conductive support 11 is, for example, preferably 0.5 g to 500 g, and more preferably 5 g to 100 g.

Next, the photosensitive layer 13 is provided.

First, a light absorber solution for forming a photosensitive layer is prepared. The light absorber solution contains MX₂ and AX which are materials of the perovskite compound (P). Here, A and X are synonymous with A and X of Formula (I). M is synonymous with M^{A1} and M^{A2} of Formula (I). In this light absorber solution, a molar ratio between MX₂ and AX is adjusted according to n (n1 and n2) of the perovskite compound (P) and m.

Next, the prepared light absorber solution is applied to the surface of the porous layer 12 or the surface of the blocking layer 14 and is dried. Therefore, the perovskite compound (P) is formed on the surface of the porous layer 12 or the surface of the blocking layer 14.

In this manner, the photosensitive layer 13 containing at least one of perovskite compound (P) is provided on the surface of the porous layer 12 or the surface of the blocking layer 14.

On the photosensitive layer 13 provided in this manner, a hole transport material solution containing a hole transport material is applied and dried to form the hole transport layer 3.

In the hole transport material solution, the concentration of the hole transport material is preferably 0.1 M (mol/L) to 1.0 M (mol/L) from the viewpoint of excellent coatability and easy intrusion up to the inside of the holes of the porous layer 12 when the porous layer 12 is provided.

After the formation of the hole transport layer 3, the second electrode 2 is formed to manufacture a photoelectric conversion element and a solar cell.

The thickness of each layer can be adjusted by appropriately changing the concentration and the number of times of application of each dispersion liquid or solution. For example, when the thick photosensitive layer 13B shown in FIG. 2 or 3 is provided, the dispersion liquid may be applied and dried a plurality of times.

The above-described respective dispersion liquids and solutions may contain additives such as a dispersion auxiliary agent and a surfactant if necessary.

Examples of the solvent or dispersion medium used in the method of manufacturing the photoelectric conversion element and the solar cell include solvents described in JP2001-291534A, but the solvent or dispersion medium is not particularly limited thereto. In the invention, an organic solvent is preferred, and an alcohol solvent, an amide solvent, a nitrile solvent, a hydrocarbon solvent, a lactone solvent, and a mixed solvent of two or more thereof are more preferred. The mixed solvent is preferably a mixed solvent of solvents selected from an alcohol solvent, an amide solvent, a nitrile solvent, and a hydrocarbon solvent. Specifically, methanol, ethanol, γ-butyrolactone, chlorobenzene, acetonitrile, dimethylformamide (DMF), dimethylacetamide, or a mixed solvent thereof is preferred.

The method of applying the solution or dispersing agent which forms each layer is not particularly limited, and known methods such as spin coating, extrusion die coating, blade coating, bar coating, screen printing, stencil printing, roll coating, curtain coating, spray coating, dip coating, ink jet printing, and dipping can be used. Among these, spin coating, screen printing, dipping, and the like are preferred.

The solar cell is manufactured by connecting an external circuit to the first electrode 1 and the second electrode 2 of the photoelectric conversion element produced as described above.

### EXAMPLES

Hereinafter, the invention will be described in more detail based on the following examples, but is not limited thereto.

The photoelectric conversion element 10A and the solar cell shown in FIG. 1 were manufactured according to the following procedures. When the photosensitive layer 13 has a large thickness, the large thickness is provided to correspond to the photoelectric conversion element 10B and the solar cell shown in FIG. 2.

### Example 1

Solar cells were manufactured using a light absorber containing the above-described perovskite compound (P¹), and the fluctuation in the photoelectric conversion efficiency was evaluated.

(Manufacturing of Photoelectric Conversion Element and Solar Cell (Sample No. 101))

A photoelectric conversion element 10 and a solar cell of the invention were manufactured according to the following procedures.

<Formation of Blocking Layer 14>

A 15 mass % isopropanol solution of titanium diisopropoxide bis(acetylacetonato) (manufactured by Sigma-Aldrich Co. LLC.) was diluted with 1-butanol to prepare a 0.02 M solution for a blocking layer.

A fluorine-doped, conductive SnO₂ film (transparent electrode 11b) was formed on a glass substrate (support 11a, thickness: 2.2 mm) to produce a conductive support 11. Using the prepared 0.02 M solution for a blocking layer, a blocking layer 14 (thickness: 50 nm) was formed on the conductive SnO₂ film at 450° C. through a spray pyrolysis method.

<Formation of Porous Layer 12>

A titanium oxide paste was prepared by adding ethyl cellulose, lauric acid, and terpineol to an ethanol dispersion liquid of titanium oxide (TiO₂, anatase, average particle diameter: 20 nm).

The prepared titanium oxide paste was applied to the blocking layer 14 through a screen printing method and was baked for 1 hour at 500° C. to obtain a baked material. When application and baking of the titanium oxide paste were performed a plurality of times, the baking temperature was adjusted such that the temperature for baking other than final baking was 130° C. The obtained, baked material of titanium oxide was dipped in a 40 mM TiCl₄ aqueous solution, and then heated for 1 hour at 60° C. Next, the resulting material was heated for 30 minutes at 500° C., and thus a porous layer 12 (thickness: 0.6 μm) formed of TiO₂ was formed.

<Formation of Photosensitive Layer 13A>

A 40% methanol solution of methylamine (27.86 mL) and an aqueous solution of 57 mass % of hydrogen iodide (hydriodic acid, 30 mL) were stirred for 2 hours at 0° C. in a flask, and then concentrated to obtain a crude material of CH₃NH₃I. The obtained crude material of CH₃NH₃I was dissolved in ethanol and recrystallized with diethyl ether. The precipitated crystals were filtered and dried under reduced pressure for 24 hours at 60° C., and thus purified CH₃NH₃I was obtained.

Next, the purified CH₃NH₃I, PbI₂, and SnI₂ were stirred and mixed at a molar ratio of 2:0.99:0.01 (in Formula (IA¹), n1=0.01) for 12 hours at 60° C. in γ-butyrolactone, and then filtered by a polytetrafluoroethylene (PTFE) syringe filter to prepare a 40 mass % light absorber solution A.

The prepared light absorber solution A was applied to the porous layer 12 through a spin coating method (for 60 seconds at 2000 rpm, then for 60 seconds at 3000 rpm), and the applied light absorber solution A was dried using a hot plate for 40 minutes at 100° C. to form a photosensitive layer 13A having a perovskite compound. The photosensitive layer 13A as a cation A¹, (Pb²⁺_{0.99}Sn²⁺_{0.01}) as a metal cation, and I⁻ as an anion X and represented by Formula (IA¹): (CH₃NH₃)(Pb_{0.99}Sn_{0.01})I₃.

In this manner, a first electrode 1A was produced.

<Formation of Hole Transport Layer 3A>

Spiro-OMeTAD (180 mg) as a hole transport material was dissolved in chlorobenzene (1 mL). To this chlorobenzene solution, an acetonitrile solution (37.5 μL) prepared by dissolving lithium-bis(trifluoromethane sulfonyl)imide (170 mg) in acetonitrile (1 mL) and t-butylpyridine (TBP, 17.5 μL) were added and mixed, and thus a hole transport material solution was prepared.

Next, the prepared hole transport material solution was applied to the photosensitive layer 13A of the first electrode 1A through a spin coating method, and the applied hole transport material solution was dried to form a hole transport layer 3A (thickness: 0.1 μm).

<Production of Second Electrode 2>

A second electrode 2 was produced by depositing gold (thickness: 0.1 μm) on the hole transport layer 3A through a deposition method.

In this manner, the photoelectric conversion element 10A and the solar cell shown in FIG. 1 were manufactured.

(Manufacturing of Photoelectric Conversion Elements and Solar Cells (Sample Nos. 102, 103, and 107 to 109))

Photoelectric conversion elements and solar cells of the invention (Sample Nos. 102, 103, and 107 to 109) were manufactured in the same manner as in the manufacturing of the photoelectric conversion element and the solar cell (Sample No. 101), except that in the manufacturing of the photoelectric conversion element and the solar cell (Sample No. 101), the mixing ratio (molar ratio) of the purified CH₃NH₃I, PbI₂, and SnI₂ in the light absorber solution A was adjusted to 2:(1−n1):n1 (n1 is synonymous with n1 of Formula (IA¹) and is shown in Table 1).

In each of the manufactured samples, the photosensitive layer contained the same perovskite compound as the perovskite compound (P^{A1}) contained in the photosensitive layer of the photoelectric conversion element and the solar cell (Sample No. 101), except that n1 of Formula (IA¹) was different.

(Manufacturing of Photoelectric Conversion Element and Solar Cell (Sample No. 104))

A photoelectric conversion element and a solar cell of the invention (Sample No. 104) were manufactured in the same manner as in the manufacturing of the photoelectric conversion element and the solar cell (Sample No. 101), except that in the manufacturing of the photoelectric conversion element and the solar cell (Sample No. 101), the following light absorber solution B was used in place of the light absorber solution A.

The photosensitive layer of the manufactured photoelectric conversion element and solar cell contained the same perovskite compound as the perovskite compound (P^{A1}) contained in the photosensitive layer of the photoelectric conversion element and the solar cell (Sample No. 101), except that n1 of Formula (IA¹) and the anion X were different.

<Preparation of Light Absorber Solution B>

A 40% methanol solution of methylamine (27.86 mL) and an aqueous solution of 57 mass % of hydrogen bromide (hydrobromic acid, 30 mL) were stirred for 2 hours at 0° C. in a flask, and then concentrated to obtain a crude material of CH₃NH₃Br. The obtained crude material of CH₃NH₃Br was dissolved in ethanol and recrystallized with diethyl ether. The precipitated crystals were filtered and dried under reduced pressure for 24 hours at 60° C., and thus purified CH₃NH₃Br was obtained. Next, the purified CH₃NH₃Br, PbBr₂, and SnBr₂ were stirred and mixed at a molar ratio of 2:0.90:0.10 (in Formula (IA¹), n1=0.10) for 12 hours at 60° C. in γ-butyrolactone, and then filtered by a polytetrafluoroethylene (PTFE) syringe filter to prepare a 40 mass % light absorber solution B.

(Manufacturing of Photoelectric Conversion Element and Solar Cell (Sample No. 105))

A photoelectric conversion element and a solar cell of the invention (Sample No. 105) were manufactured in the same manner as in the manufacturing of the photoelectric conversion element and the solar cell (Sample No. 101), except that in the manufacturing of the photoelectric conversion element and the solar cell (Sample No. 101), the following light absorber solution C was used in place of the light absorber solution A.

The photosensitive layer of the manufactured photoelectric conversion element and solar cell contained the same perovskite compound as the perovskite compound (P^{A1}) contained in the photosensitive layer of the photoelectric conversion element and the solar cell (Sample No. 101), except that n1 of Formula (IA¹) and the anion X were different.

<Preparation of Light Absorber Solution C>

A 40% methanol solution of methylamine (27.86 mL) and an aqueous solution of 57 mass % of hydrogen iodide (hydriodic acid, 30 mL) were stirred for 2 hours at 0° C. in a flask, and then concentrated to obtain a crude material of CH₃NH₃I. The obtained crude material of CH₃NH₃I was dissolved in ethanol and recrystallized with diethyl ether. The precipitated crystals were filtered and dried under reduced pressure for 24 hours at 60° C., and thus purified CH₃NH₃I was obtained. Next, the purified CH₃NH₃I, PbBr₂, PbI₂, and SnI₂ were stirred and mixed at a molar ratio of 2:0.50:0.40:0.10 (in Formula (IA¹), n1=0.10, and in Formula (X1), m1=1) for 12 hours at 60° C. in γ-butyrolactone, and then filtered by a polytetrafluoroethylene (PTFE) syringe filter to prepare a 40 mass % light absorber solution C.

(Manufacturing of Photoelectric Conversion Element and Solar Cell (Sample No. 106))

A photoelectric conversion element and a solar cell of the invention (Sample No. 106) were manufactured in the same manner as in the manufacturing of the photoelectric conversion element and the solar cell (Sample No. 101), except that in the manufacturing of the photoelectric conversion element and the solar cell (Sample No. 101), the following light absorber solution D was used in place of the light absorber solution A.

The photosensitive layer of the manufactured photoelectric conversion element and solar cell contained the same perovskite compound as the perovskite compound (P^{A1}) contained in the photosensitive layer of the photoelectric conversion element and the solar cell (Sample No. 101), except that n1 of Formula (IA¹) and the anion X were different.

<Preparation of Light Absorber Solution D>

A 40% methanol solution of methylamine (27.86 mL) and an aqueous solution of 57 mass % of hydrogen iodide (hydriodic acid, 30 mL) were stirred for 2 hours at 0° C. in a flask, and then concentrated to obtain a crude material of CH₃NH₃I. The obtained crude material of CH₃NH₃I was dissolved in ethanol and recrystallized with diethyl ether. The precipitated crystals were filtered and dried under reduced pressure for 24 hours at 60° C., and thus purified CH₃NH₃I was obtained. Next, the purified CH₃NH₃I, PbCl₂, PbI₂, and SnI₂ were stirred and mixed at a molar ratio of 2:0.50:0.40:0.10 (in Formula (IA¹), n1=0.10, and in Formula (X1), m1=1) for 12 hours at 60° C. in γ-butyrolactone, and then filtered by a polytetrafluoroethylene (PTFE) syringe filter to prepare a 40 mass % light absorber solution D.

(Manufacturing of Photoelectric Conversion Element and Solar Cell (Sample No. c101))

A photoelectric conversion element and a solar cell for comparison (Sample No. c101) were manufactured in the same manner as in the manufacturing of the photoelectric conversion element and the solar cell (Sample No. 101), except that in the manufacturing of the photoelectric conversion element and the solar cell (Sample No. 101), the mixing ratio (molar ratio) of the purified CH₃NH₃I, PbI₂, and SnI₂ in the light absorber solution A was adjusted to 2:1:0 (in Formula (IA¹), n1=0).

(Evaluation of Fluctuation in Photoelectric Conversion Efficiency)

The fluctuation in the photoelectric conversion efficiency was evaluated as follows for each of the sample Nos. of the solar cells.

That is, for each sample No., ten solar cell samples were manufactured in the same manner as in the manufacturing method, and each of the ten samples was subjected to a cell characteristic test to measure a photoelectric conversion efficiency (η/%). The cell characteristic test was performed by applying 1000 W/m² of artificial solar light passing through an AM 1.5 filter from a xenon lamp using a solar simulator “WXS-85H” (manufactured by Wacom Co., Ltd.). Current-voltage characteristics were measured using a I-V tester, and the photoelectric conversion efficiency (η/%) was obtained.

An average of the photoelectric conversion efficiencies obtained in this manner was calculated. This average was set to “1” and provided as a standard. A photoelectric conversion efficiency (relative value) of each of the ten solar cell samples with respect to the average “1” (standard) was obtained.

The ten solar cell samples were classified into two groups consisting of a sample group (referred to as “Not Less Than Average” in Table 1) in which the obtained photoelectric conversion efficiencies (relative values) were high photoelectric conversion efficiencies which were not less than the average “1” and a sample group (referred to as “Less Than Average” in Table 1) exhibiting lower photoelectric conversion efficiencies than the average “1”. A difference (absolute value) between the photoelectric conversion efficiency (relative value) and the standard was calculated for each of the samples belonging to each group, and the fluctuation in the photoelectric conversion efficiency was evaluated based on the following evaluation standards.

Specifically, in the sample group exhibiting higher photoelectric conversion efficiencies than the average, a sample having the largest difference (absolute value) was evaluated to know which one of the ranges of the following evaluation standards the sample belongs to. Similarly, in the sample group exhibiting lower photoelectric conversion efficiencies than the average, a sample having the largest difference (absolute value) was evaluated to know which one of the ranges of the following evaluation standards the sample belongs to.

In the invention, in the evaluation of the fluctuation in the photoelectric conversion efficiency, when the result of “less than average” is D or higher and the result of “not less than average” is C or higher, the target level is achieved. In practical use, both the results of “less than average” and “not less than average” are preferably B or higher, and more preferably A or B+.

(Evaluation Standards)

A: 0 to 0.15

B+: greater than 0.15 to 0.19

B: greater than 0.19 to 0.23

C: greater than 0.23 to 0.27

D: greater than 0.27 to 0.31

E: greater than 0.31

TABLE 1

| | | | | | | | | | Evaluation of | | |
|---|---|---|---|---|---|---|---|---|---|---|---|
| | | | | | | | | | Fluctuation | | |
| | | | | | | | | | | Not | |
| | | | | | | | | | Less | Less | |
| Sample | Perovskite Compound | | | | | | | | Than | Than | |
| No. | R^{A1} | M^{A1} | M^{A2} | n1 | X | X^{A1} | X^{A2} | m1 | Average | Average | Remarks |
| c101 | —CH₃ | Pb | — | 0 | I | — | — | — | E | D | Comparative |
| | | | | | | | | | | | Example |
| 101 | —CH₃ | Pb | Sn | 0.01 | I | — | — | — | B | C | Example |
| 102 | —CH₃ | Pb | Sn | 0.05 | I | — | — | — | B⁺ | B | Example |
| 103 | —CH₃ | Pb | Sn | 0.10 | I | — | — | — | B⁺ | B | Example |
| 104 | —CH₃ | Pb | Sn | 0.10 | Br | — | — | — | B⁺ | B | Example |
| 105 | —CH₃ | Pb | Sn | 0.10 | — | I | Br | 1 | A | B | Example |
| 106 | —CH₃ | Pb | Sn | 0.10 | — | I | Cl | 1 | A | B | Example |
| 107 | —CH₃ | Pb | Sn | 0.20 | I | — | — | — | B⁺ | B | Example |
| 108 | —CH₃ | Pb | Sn | 0.25 | I | — | — | — | B | C | Example |
| 109 | —CH₃ | Pb | Sn | 0.50 | I | — | — | — | B | C | Example |

As shown in Table 1, all of the photoelectric conversion elements and the solar cells of Sample Nos. 101 to 109 have a photosensitive layer containing a compound (P^{A1}) having a perovskite crystal structure represented by Formula (IA¹). These photoelectric conversion elements and solar cells were found to have less fluctuation in the photoelectric conversion efficiency. Particularly, when n1 of Formula (IA¹) was within a range of 0.05 to 0.20 (Sample Nos. 102 to 107), the fluctuation in the photoelectric conversion efficiency was found to be further reduced. In addition, when the anionic atom X of the compound (P^{A1}) having a perovskite crystal structure represented by Formula (IA¹) satisfied Formula (X1) (Sample Nos. 105 and 106), the fluctuation in the photoelectric conversion efficiency was found to be particularly reduced.

In the photoelectric conversion elements and the solar cells (Sample Nos. 101 to 109) having a photosensitive layer containing the compound (P^{A1}) having a perovskite crystal structure, the group of “less than average” had less fluctuation than the group of “not less than average”.

The solar cell (Sample No. c101) having a photosensitive layer which did not contain the perovskite compound (P) used in the invention had a great fluctuation in the photoelectric conversion efficiency.

### Example 2

Solar cells were manufactured using a light absorber containing the above-described perovskite compound (P′), and the fluctuation in the photoelectric conversion efficiency was evaluated.

(Manufacturing of Photoelectric Conversion Element and Solar Cell (Sample No. 201))

A photoelectric conversion element and a solar cell of the invention (Sample No. 201) were manufactured in the same manner as in the manufacturing of the photoelectric conversion element and the solar cell (Sample No. 101), except that in the manufacturing of the photoelectric conversion element and the solar cell (Sample No. 101), the following light absorber solution E was used in place of the light absorber solution A.

The photosensitive layer of the manufactured photoelectric conversion element and solar cell contained a perovskite compound (P^{B1}) having a perovskite crystal structure with CH₃CH₂—NH₃⁺ as a cation A¹, (Pb²⁺_{0.99}Sn²⁺_{0.01}) as a metal cation, and I⁻ as an anion X and represented by Formula: (IB¹): (CH₃CH₂—NH₃)₂(Pb_{0.99}Sn_{0.01})I₄.

<Preparation of Light Absorber Solution E>

A 40% ethanol solution of ethylamine and an aqueous solution of 57 mass % of hydrogen iodide were stirred for 2 hours at 0° C. in a flask, and then concentrated to obtain a crude material of CH₃CH₂NH₃I. The obtained crude material was dissolved in ethanol and recrystallized with diethyl ether. The precipitated crystals were filtered and dried under reduced pressure for 12 hours at 60° C., and thus purified CH₃CH₂NH₃I was obtained. Next, the purified CH₃CH₂NH₃I, PbI₂, and SnI₂ were stirred and mixed at a molar ratio of 3:0.99:0.01 (in Formula (IB¹), n1=0.01) for 5 hours at 60° C. in dimethylformamide (DMF), and then filtered by a polytetrafluoroethylene (PTFE) syringe filter to prepare a 40 mass % light absorber solution E.

(Manufacturing of Photoelectric Conversion Elements and Solar Cells (Sample Nos. 202 to 206))

Photoelectric conversion elements and solar cells of the invention (Sample Nos. 202 to 206) were manufactured in the same manner as in the manufacturing of the photoelectric conversion element and the solar cell (Sample No. 201), except that in the manufacturing of the photoelectric conversion element and the solar cell (Sample No. 201), the mixing ratio (molar ratio) of the purified CH₃CH₂NH₃I, PbI₂, and SnI₂ in the light absorber solution E was adjusted to 3:(1−n1):n1 (n1 is synonymous with n1 of Formula (IB¹) and is shown in Table 2).

In each of the manufactured samples, the photosensitive layer contained the same perovskite compound as the perovskite compound (P^{B1}) contained in the photosensitive layer of the photoelectric conversion element and the solar cell (Sample No. 201), except that n1 of Formula (IB¹) was different.

(Manufacturing of Photoelectric Conversion Element and Solar Cell (Sample No. c201))

A photoelectric conversion element and a solar cell for comparison (Sample No. c201) were manufactured in the same manner as in the manufacturing of the photoelectric conversion element and the solar cell (Sample No. 201), except that in the manufacturing of the photoelectric conversion element and the solar cell (Sample No. 201), the mixing ratio (molar ratio) of the purified CH₃CH₂NH₃I, PbI₂, and SnI₂ in the light absorber solution E was adjusted to 3:1.0:0 (in Formula (IB¹), n1=0).

The photosensitive layer of the photoelectric conversion element and the solar cell contained the same perovskite compound as the perovskite compound (P^{B1}) contained in the photosensitive layer of the photoelectric conversion element and the solar cell (Sample No. 201), except that n1 of Formula (IB¹) was different.

(Evaluation of Fluctuation in Photoelectric Conversion Efficiency)

The fluctuation in the photoelectric conversion efficiency in the photoelectric conversion elements and the solar cells (Sample Nos. 201 to 206 and c201) was evaluated in the same manner as in “Evaluation of Fluctuation in Photoelectric Conversion Efficiency” of Example 1. The results are shown in Table 2.

TABLE 2

| | | | | | | Evaluation of | | |
|---|---|---|---|---|---|---|---|---|
| | | | | | | Fluctuation | | |
| | | | | | | | Not Less | |
| Sample | Perovskite Compound | | | | | Less Than | Than | |
| No. | R^{A1} | M^{A1} | M^{A2} | n1 | X | Average | Average | Remarks |
| c201 | —CH₂CH₃ | Pb | — | 0 | I | E | C | Comparative |
| | | | | | | | | Example |
| 201 | —CH₂CH₃ | Pb | Sn | 0.01 | I | B | B | Example |
| 202 | —CH₂CH₃ | Pb | Sn | 0.05 | I | B⁺ | A | Example |
| 203 | —CH₂CH₃ | Pb | Sn | 0.10 | I | B⁺ | A | Example |
| 204 | —CH₂CH₃ | Pb | Sn | 0.20 | I | B⁺ | A | Example |
| 205 | —CH₂CH₃ | Pb | Sn | 0.25 | I | B | B | Example |
| 206 | —CH₂CH₃ | Pb | Sn | 0.50 | I | B | B | Example |

As shown in Table 2, all of the photoelectric conversion elements and the solar cells of Sample Nos. 201 to 206 have a photosensitive layer containing a compound (P^{B1}) having a perovskite crystal structure represented by Formula (IB¹). These photoelectric conversion elements and solar cells were found to have less fluctuation in the photoelectric conversion efficiency. This effect of preventing the fluctuation in the photoelectric conversion efficiency showed the same tendency as the effect of preventing the fluctuation in the photoelectric conversion efficiency of Example 1, except that the group of “not less than average” had less fluctuation than the group of “less than average”.

The solar cell (Sample No. c201) having a photosensitive layer which did not contain the perovskite compound (P) used in the invention had a great fluctuation in the photoelectric conversion efficiency.

### Example 3

Solar cells were manufactured using a light absorber containing the above-described perovskite compound (P²), and the fluctuation in the photoelectric conversion efficiency was evaluated.

(Manufacturing of Photoelectric Conversion Element and Solar Cell (Sample No. 301))

A photoelectric conversion element and a solar cell of the invention (Sample No. 301) were manufactured in the same manner as in the manufacturing of the photoelectric conversion element and the solar cell (Sample No. 101), except that in the manufacturing of the photoelectric conversion element and the solar cell (Sample No. 101), the following light absorber solution F was used in place of the light absorber solution A.

The photosensitive layer of the photoelectric conversion element and the solar cell contained a compound (P^{B2}) having a perovskite crystal structure represented by (CF₃CH₂—NH₃)₂PbI₄ with CF₃CH₂—NH₃⁺ as a cation A², Pb²⁺ as a metal cation, and I⁻ as an anion X.

<Preparation of Light Absorber Solution F>

The light absorber solution F was prepared in the same manner as in the preparation of the light absorber solution E, except that in the preparation of the light absorber solution E, a 40% ethanol solution of 2,2,2-trifluoroethylamine (CF₃CH₂NH₂) was used in place of the 40% ethanol solution of ethylamine, and the synthesized, purified CF₃CH₂NH₃I and PbI₂ were mixed at a molar ratio of 3:1.0 (n2=0 in Formula (I²)).

(Manufacturing of Photoelectric Conversion Elements and Solar Cells (Sample Nos. 302 to 307))

Photoelectric conversion elements and solar cells of the invention (Sample Nos. 302 to 307) were manufactured in the same manner as in the manufacturing of the photoelectric conversion elements and the solar cells (Sample Nos. 201 to 206), except that in the manufacturing of the photoelectric conversion elements and the solar cells (Sample Nos. 201 to 206), purified CF₃CH₂NH₃I synthesized in the same manner as in the case of the light absorber solution F was used in place of the purified CH₃CH₂NH₃I synthesized in the case of the light absorber solution E.

The photosensitive layers of the photoelectric conversion elements and the solar cells contained the same perovskite compound as the perovskite compound (P^{B2}) contained in the photosensitive layer of the photoelectric conversion element and the solar cell (Sample No. 301), except that n2 of Formula (I²) was different.

(Manufacturing of Photoelectric Conversion Element and Solar Cell (Sample No. 308))

A photoelectric conversion element and a solar cell of the invention (Sample No. 308) were manufactured in the same manner as in the manufacturing of the photoelectric conversion element and the solar cell (Sample No. 101), except that in the manufacturing of the photoelectric conversion element and the solar cell (Sample No. 101), the following light absorber solution G was used in place of the light absorber solution A and the drying conditions of the light absorber solution G were changed to 160° C. and 40 minutes.

The photosensitive layer of the photoelectric conversion element and the solar cell contained a perovskite compound (P^{A2}) having a perovskite crystal structure with [CH(═NH)—NH₃]⁺ as a cation A², Pb²⁺ as a metal atom M, and I⁻ as an anion X and represented by Formula: (IA²): [CH(═NH)—NH₃]PbI₃.

<Preparation of Light Absorber Solution G>

Formamidine acetate and an aqueous solution of 57 mass % of hydrogen iodide, containing the hydrogen iodide 2 eq. based on the formamidine acetate, were stirred for 1 hour at 0° C. in a flask, and then further stirred and mixed for 1 hour after the temperature was raised to 50° C. The obtained solution was concentrated to obtain a crude material of formamidine-hydrogen iodate. The obtained crude material was recrystallized with diethyl ether, and the precipitated crystals were filtered and dried under reduced pressure for 10 hours at 50° C. Thus, purified formamidine-hydrogen iodate was obtained. Next, the purified formamidine-hydrogen iodate and PbI₂ were stirred and mixed at a molar ratio of 2:1 (in Formula (IA²), n2=0) for 3 hours at 60° C. in dimethylformamide (DMF), and then filtered by a polytetrafluoroethylene (PTFE) syringe filter to prepare a 40 mass % light absorber solution G

(Manufacturing of Photoelectric Conversion Element and Solar Cell (Sample No. 309))

A photoelectric conversion element and a solar cell of the invention (Sample No. 309) were manufactured in the same manner as in the manufacturing of the photoelectric conversion element and the solar cell (Sample No. 308), except that in the manufacturing of the photoelectric conversion element and the solar cell (Sample No. 308), the following light absorber solution H was used in place of the light absorber solution G.

The photosensitive layer of the manufactured photoelectric conversion element and solar cell contained a perovskite compound (P^{A2}) having a perovskite crystal structure with [CH(═NH)—NH₃]⁺ as a cation A², (Pb²⁺_{0.90}Sn²⁺_{0.10}) as a metal cation, and I⁻ as an anion X and represented by Formula: (IA²): [CH(═NH)—NH₃](Pb_{0.90}Sn_{0.10})I₃.

<Preparation of Light Absorber Solution H>

The light absorber solution H was prepared in the same manner as in the preparation of the light absorber solution G, except that in the preparation of the light absorber solution G, the purified formamidine-hydrogen iodate, PbI₂, and SnI₂ were mixed at a molar ratio of 2:0.90:0.10 (n2=0.10 in Formula (IA²)).

(Evaluation of Fluctuation in Photoelectric Conversion Efficiency)

The fluctuation in the photoelectric conversion efficiency in the photoelectric conversion elements and the solar cells (Sample Nos. 301 to 309) was evaluated in the same manner as in “Evaluation of Fluctuation in Photoelectric Conversion Efficiency” of Example 1. The results are shown in Table 3.

TABLE 3

| | | | | | | Evaluation of | | |
|---|---|---|---|---|---|---|---|---|
| | | | | | | Fluctuation | | |
| | | | | | | | Not Less | |
| Sample | Perovskite Compound | | | | | Less Than | Than | |
| No. | R^{A2} | M^{A1} | M^{A2} | n2 | X | Average | Average | Remarks |
| 301 | —CH₂CF₃ | Pb | — | 0 | I | C | C | Example |
| 302 | —CH₂CF₃ | Pb | Sn | 0.01 | I | B⁺ | B | Example |
| 303 | —CH₂CF₃ | Pb | Sn | 0.05 | I | A | A | Example |
| 304 | —CH₂CF₃ | Pb | Sn | 0.10 | I | A | A | Example |
| 305 | —CH₂CF₃ | Pb | Sn | 0.20 | I | A | A | Example |
| 306 | —CH₂CF₃ | Pb | Sn | 0.25 | I | B⁺ | B | Example |
| 307 | —CH₂CF₃ | Pb | Sn | 0.50 | I | B⁺ | B | Example |
| 308 | —C(═NH)H | Pb | — | 0 | I | D | C | Example |
| 309 | —C(═NH)H | Pb | Sn | 0.10 | I | B⁺ | A | Example |

As shown in Table 3, all of the photoelectric conversion elements and the solar cells of Sample Nos. 301 to 309 have a photosensitive layer containing a compound (P²) having a perovskite crystal structure represented by Formula (I²). Even when the type of the cation R^{A2} and the molar content ratio n2 of the metal cation M^{A2} were changed, these photoelectric conversion elements and solar cells had less fluctuation in the photoelectric conversion efficiency, and showed the same tendency as Example 1.

As is obvious from the results of Tables 1 to 3, the photoelectric conversion element and the solar cell were found to show a reduced fluctuation in the photoelectric conversion efficiency when containing, as a light absorber, at least one of compound (P) having a perovskite crystal structure represented by Formula (I).

### EXPLANATION OF REFERENCES

1A, 1B, 1C: first electrode
11: conductive support
11a: support
11b: transparent electrode
12: porous layer
13A, 13B, 13C: photosensitive layer
14: blocking layer
2: second electrode
3A, 3B, 3C: hole transport layer
6: external circuit (lead)
10A, 10B, 10C: photoelectric conversion element
100A, 100B, 100C: system in which photoelectric conversion element is applied for use in cell
M: electric motor

What is claimed is:

1. A photoelectric conversion element comprising:
a first electrode which has a photosensitive layer containing a light absorber on a conductive support;
a second electrode which is opposed to the first electrode; and
a hole transport layer which is provided between the first electrode and the second electrode,
wherein the light absorber contains at least one of compound (P) having a perovskite crystal structure represented by the following Formula (I),
Aₐ(M^{A1}₍₁₋ₙ₎M^{A2}ₙ)_{mA}Xₓ Formula (I):
wherein A represents a cationic group represented by the following Formula (A), M^{A1} and M^{A2} represent metal atoms different from each other, n represents a number satisfying 0≦n≦0.5, X represents an anionic atom, a represents 1 or 2, mA represents 1, and a, mA, and x satisfy a+2 mA=x,
R^{A}—NH₃ Formula (A):
wherein R^{A} represents an alkyl group, a cycloalkyl group, an alkenyl group, an alkynyl group, an aryl group, a heteroaryl group, or a group represented by the following Formula (1), which may have a substituent, and the alkyl group has a substituent when n represents a number satisfying 0≦n<0.01, and 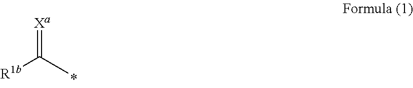
wherein X^{a} represents NR^{1c}, an oxygen atom, or a sulfur atom, each of R^{1b} and R^{1c} independently represents a hydrogen atom or a substituent, and * represents a bonding position with the N atom of Formula (A).

2. The photoelectric conversion element according to claim 1,
wherein the compound (P) having a perovskite crystal structure includes a compound (P^{A}) represented by the following Formula (IA),
A(M^{A1}₍₁₋ₙ₎M^{A2}ₙ)X₃ Formula (IA):
wherein A, M^{A1}, M^{A2}, n, and X are synonymous with A, M^{A1}, M^{A2}, n, and X of Formula (I).

3. The photoelectric conversion element according to claim 1,
wherein the compound (P) having a perovskite crystal structure includes a compound (P^{B}) represented by the following Formula (TB),
A₂(M^{A1}₍₁₋ₙ₎M^{A2}ₙ)X₄ Formula (IB):
wherein A, M^{A1}, M^{A2}, n, and X are synonymous with A, M^{A1}, M^{A2}, n, and X of Formula (I).

4. The photoelectric conversion element according to claim 1,
wherein when n represents a number satisfying 0.01≦n≦0.5, A is a cationic group represented by the following Formula (A1),
R^{A1}—NH₃ Formula (A1):
wherein R^{A1} represents an unsubstituted alkyl group.

5. The photoelectric conversion element according to claim 1,
wherein A is a cationic group represented by the following Formula (A2),
R^{A2}—NH₃ Formula (A2):
wherein R^{A2} represents an alkyl group having a substituent, or a cycloalkyl group, an alkenyl group, an alkynyl group, an aryl group, a heteroaryl group, or a group represented by Formula (1), which may have a substituent.

6. The photoelectric conversion element according to claim 1,
wherein n represents a number satisfying 0.05≦n≦0.20.

7. The photoelectric conversion element according to claim 1,
wherein one of M^{A1} and M^{A2} is a Pb atom and the other is a Sn atom.

8. The photoelectric conversion element according to claim 1,
wherein M^{A1} is a Pb atom and M^{A2} is a Sn atom.

9. The photoelectric conversion element according to claim 1,
wherein X is a halogen atom.

10. The photoelectric conversion element according to claim 1,
wherein when a is 1, X is represented by the following Formula (X1),
X^{A1}₍₃₋ₘ₁₎X^{A2}ₘ₁ Formula (X1):
wherein X^{A1} and X^{A2} represent anionic atoms different from each other, and m1 represents a number of 0.01 to 2.99.

11. The photoelectric conversion element according to claim 1,
wherein when a is 2, X is represented by the following Formula (X2),
X^{A1}₍₄₋ₘ₂₎X^{A2}ₘ₂ Formula (X2):
wherein X^{A1} and X^{A2} represent anionic atoms different from each other, and m2 represents a number of 0.01 to 3.99.

12. The photoelectric conversion element according to claim 10,
wherein X^{A1} and X^{A2} are halogen atoms different from each other.

13. The photoelectric conversion element according to claim 11,
wherein X^{A1} and X^{A2} are halogen atoms different from each other.

14. The photoelectric conversion element according to claim 1,
wherein the substituent has at least one selected from the group consisting of an alkyl group, a cycloalkyl group, an alkenyl group, an alkynyl group, an alkoxy group, an alkylthio group, a mercapto group, an aryloxy group, an amino group, a carboxy group, an acyl group, an alkoxycarbonyl group, an aryloxycarbonyl group, an alkyl carbonyloxy group, an aryl carbonyloxy group, a halogen atom, a cyano group, an aryl group, and a heteroaryl group.

15. The photoelectric conversion element according to claim 1,
wherein the substituent is a halogen atom.

16. The photoelectric conversion element according to claim 1,
wherein the substituent is an alkyl group substituted with a halogen atom.

17. The photoelectric conversion element according to claim 2,
wherein the substituent is an alkyl group substituted with a halogen atom.

18. The photoelectric conversion element according to claim 3,
wherein the substituent is an alkyl group substituted with a halogen atom.

19. The photoelectric conversion element according to claim 6,
wherein the substituent is an alkyl group substituted with a halogen atom.

20. A solar cell comprising:
the photoelectric conversion element according to claim 1.
